(19) United States
(12) Patent Application Publication
(10) Pub. No.: US 2026/0304757 A1
(43) Pub. Date: Oct. 1, 2026

(54) SEMICONDUCTOR DEVICE

(71) Applicant: SAMSUNG ELECTRONICS CO., LTD., Suwon-si (KR)

(72) Inventors: Jiwon KIM, Suwon-si (KR); Joo Sung KIM, Suwon-si (KR); Inseok YANG, Suwon-si (KR)

(73) Assignee: SAMSUNG ELECTRONICS CO., LTD., Suwon-si (KR)

(21) Appl. No.: 19/381,065

(22) Filed: Nov. 6, 2025

(30) Foreign Application Priority Data
Mar. 26, 2025 (KR) 10-2025-0038818

(51) Int. Cl. H10B 12/00

(52) U.S. Cl. CPC H10B 12/50; H10B 12/09; H10B 12/315

(57) ABSTRACT

The present disclosure relates to a semiconductor device, and according to an embodiment, the semiconductor device includes a substrate including a cell array region and a core/periphery region around the cell array region, a circuit wiring on the core/periphery region of the substrate, a signal wiring spaced apart from the circuit wiring in a direction perpendicular to an upper surface of the substrate, a contact plug connecting the circuit wiring and the signal wiring, an etch stop layer surrounding an outer peripheral surface of an upper portion of the contact plug, and a wiring insulating layer covering an upper surface of the contact plug and an upper surface of the etch stop layer and covering a side surface of the signal wiring, wherein a lower surface of the signal wiring is positioned at a higher level than a lower surface of the etch stop layer.

### CROSS-REFERENCE TO RELATED APPLICATION

This application claims priority to and the benefit of Korean Patent Application No. 10-2025-0038818 filed with the Korean Patent Office on Mar. 26, 2025, the entire contents of which are incorporated herein by reference.

### BACKGROUND

### a. Field

The present disclosure relates to a semiconductor device.

### b. Description of the Related Art

A semiconductor is a material that belongs to the intermediate region between conductors and insulators, and conducts electricity under certain conditions. Using these semiconductor materials, various semiconductor devices may be manufactured, such as memory devices. These semiconductor devices may be used in a variety of electronic devices.

As electronic devices become more miniaturized and highly integrated, there is a need to form fine patterns in semiconductor devices. As the width of these fine patterns gradually decreases, the manufacturing process becomes more challenging, and the defect rate of semiconductor devices may increase.

### SUMMARY

The embodiments are directed to providing a semiconductor device having reduced parasitic capacitance in the wiring and improved reliability.

A semiconductor device according to an embodiment comprises a substrate including a cell array region and a core/periphery region around the cell array region, a circuit wiring on the core/periphery region of the substrate, a signal wiring spaced apart from the circuit wiring in a direction perpendicular to an upper surface of the substrate, a contact plug connecting the circuit wiring and the signal wiring, an etch stop layer surrounding an outer surface of an upper portion of the contact plug, and a wiring insulating layer covering an upper surface of the contact plug and an upper surface of the etch stop layer and covering a side surface of the signal wiring, wherein a lower surface of the signal wiring is positioned at a higher level than a lower surface of the etch stop layer.

A semiconductor device according to an embodiment comprises a substrate including a cell array region and a core/periphery region around the cell array region, a circuit wiring on the core/periphery region of the substrate, an insulating layer on the cell array region and the core/periphery region of the substrate and covering the circuit wiring, a signal wiring and a wiring insulating layer on the insulating layer, the wiring insulating layer covering a side surface of the signal wiring, an etch stop layer between the insulating layer and the wiring insulating layer, and a contact plug connecting the signal wiring and the circuit wiring, wherein an upper surface of the contact plug is in contact with the signal wiring and the wiring insulating layer, and wherein a side surface of the contact plug is in contact with the etch stop layer and the insulating layer.

A semiconductor device according to an embodiment comprises a substrate including a cell array region and a core/periphery region around the cell array region, a circuit wiring on the core/periphery region of the substrate, an insulating layer on the cell array region and the core/periphery region of the substrate and covering the circuit wiring, a signal wiring and a wiring insulating layer on the insulating layer, the wiring insulating layer covering a side surface of the signal wiring, an etch stop layer between the insulating layer and the wiring insulating layer, and a contact plug connecting the signal wiring and the circuit wiring, wherein the etch stop layer is in contact with a side surface of the contact plug and in contact with a lower surface of the signal wiring.

A method for manufacturing a semiconductor device according to an embodiment includes forming an insulating layer covering a capacitor on a cell array region of a substrate and circuit wiring on a core/periphery region around the cell array region, forming an etch stop layer on an upper surface of the insulating layer, forming a hard mask layer on the etch stop layer, patterning the hard mask layer and the etch stop layer, etching the insulating layer using the hard mask layer as an etching mask to form a contact trench, removing the hard mask layer, depositing a contact plug material layer on an inner surface of the contact trench and on an upper surface of the etch stop layer, performing a planarization process to form a contact plug having an upper surface at the same level as the upper surface of the etch stop layer, forming a wiring insulating layer on the upper surface of the contact plug and the upper surface of the etch stop layer, etching the wiring insulating layer to expose the upper surface of the contact plug and the upper surface of the etch stop layer, thereby forming a wiring trench, and forming a signal wiring in the wiring trench.

A lower surface of the signal wiring may be in contact with the upper surface of the contact plug and the upper surface of the etch stop layer.

The upper surface of the contact plug may be in contact with the signal wiring and the wiring insulating layer, and a side surface of the contact plug may be in contact with the etch stop layer and the insulating layer.

The method may further include forming a sacrificial layer after forming the etching stop layer, wherein the hard mask layer may be formed on the sacrificial layer. In the planarization process, the sacrificial layer may be completely removed and the upper surface of the etch stop layer may be exposed.

After forming the contact trench, a cleaning process may be performed to further etch the insulating layer. In the cleaning process, a material having a high etching selectivity of the insulating layer with respect to the etch stop layer may be used. After the cleaning process, a diameter of an opening of the etch stop layer corresponding to the contact trench may be smaller than a maximum diameter of the contact trench.

A diameter of a portion of the contact plug positioned within the opening in the etch stop layer may be smaller than a maximum diameter of a portion of the contact plug positioned within the contact trench.

In forming the wiring trench, an upper portion of the etch stop layer may be etched together with the wiring insulating layer. In etching the wiring insulating layer, a material having a low etching selectivity of the wiring insulating layer with respect to the etch stop layer and a high etching selectivity of the wiring insulating layer with respect to the contact plug may be used. An upper surface of the etch stop layer forming a bottom surface of the wiring trench may be positioned at a lower level than the upper surface of the contact plug.

According to embodiments, the parasitic capacitance may be reduced by lowering the dielectric constant between adjacent wirings and between wirings and adjacent contact plugs. In addition, the reliability of the semiconductor device may be improved by preventing short circuits and reducing leakage current through an increase in the distance between adjacent wirings and between wirings and adjacent contact plugs.

### BRIEF DESCRIPTION OF THE DRAWINGS

FIG. 1 is a plan view showing a semiconductor device according to an embodiment.

FIG. 2 is a plan view showing a portion of a semiconductor device according to an embodiment.

FIG. 3 is a cross-sectional view taken along lines A-A', B-B', and C-C' of FIG. 2.

FIG. 4 is an enlarged cross-sectional view showing the R region of FIG. 3.

FIG. 5 is an enlarged cross-sectional view showing a portion of a semiconductor device according to an embodiment.

FIG. 6 is an enlarged cross-sectional view of the R region in FIG. 3.

FIG. 7 is an enlarged cross-sectional view showing a portion of a semiconductor device according to an embodiment.

FIG. 8 is an enlarged cross-sectional view of the R region in FIG. 3.

FIG. 9 is an enlarged cross-sectional view showing a portion of a semiconductor device according to an embodiment.

FIG. 10 is an enlarged cross-sectional view of the R region in FIG. 3.

FIG. 11 is an enlarged cross-sectional view showing a portion of a semiconductor device according to an embodiment.

FIG. 12 is a cross-sectional view showing a cell array region and a core/periphery region of a semiconductor device according to an embodiment.

FIGS. 13, 14, 15, 16, 17, 18, 19, 20, 21 and 22 are cross-sectional views showing a portion of a manufacturing process of a semiconductor device according to an embodiment.

FIGS. 23, 24, 25, 26, 27 and 28 are cross-sectional views showing a portion of a manufacturing process of a semiconductor device according to an embodiment.

### DETAILED DESCRIPTION OF THE EMBODIMENTS

Hereinafter, various embodiments of the present invention will be described in detail with reference to the attached drawings so that a person having ordinary skill in the art to which the present invention pertains may easily implement the invention. The present invention may be embodied in many different forms and is not limited to the embodiments described herein.

In order to clearly explain the present invention, parts irrelevant to the description are omitted, and the same reference numerals are used for identical or similar components throughout the specification.

In addition, the size and thickness of each component shown in the drawing are arbitrarily shown for convenience of explanation, so the present invention is not necessarily limited to what is shown. To clearly represent the various layers and areas in the drawing, the thickness is enlarged and shown. And in the drawing, for convenience of explanation, the thickness of some layers and areas is exaggerated.

Also, when we say that a part, such as a layer, membrane, region, or plate, is "on" or "above" another part, this includes not only cases where it is "directly on" the other part, but also cases where there are other parts in between. Conversely, when we say that a part is "directly on" another part, we mean that there is no other part in between. Also, being "above" or "on" a reference part means being located above or below the reference part, and does not necessarily mean being located "above" or "on" the opposite direction of gravity.

Additionally, throughout the specification, whenever a part is said to "include" a component, this does not mean that it excludes other components, but rather that it may include other components, unless otherwise specifically stated.

Additionally, throughout the specification, when we say "in a plan view", we mean when the target portion is viewed from above, and when we say "in a cross-sectional view", we mean when the target portion is viewed from the side in a cross-section cut vertically.

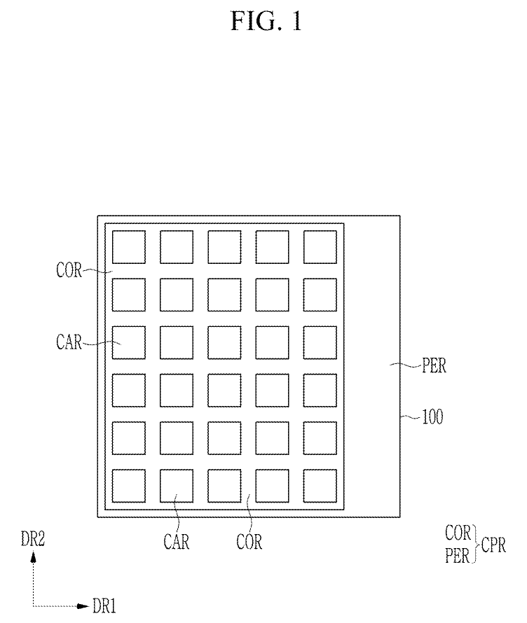

Hereinafter, a semiconductor device according to an embodiment will be described with reference to FIGS. 1 to 5.

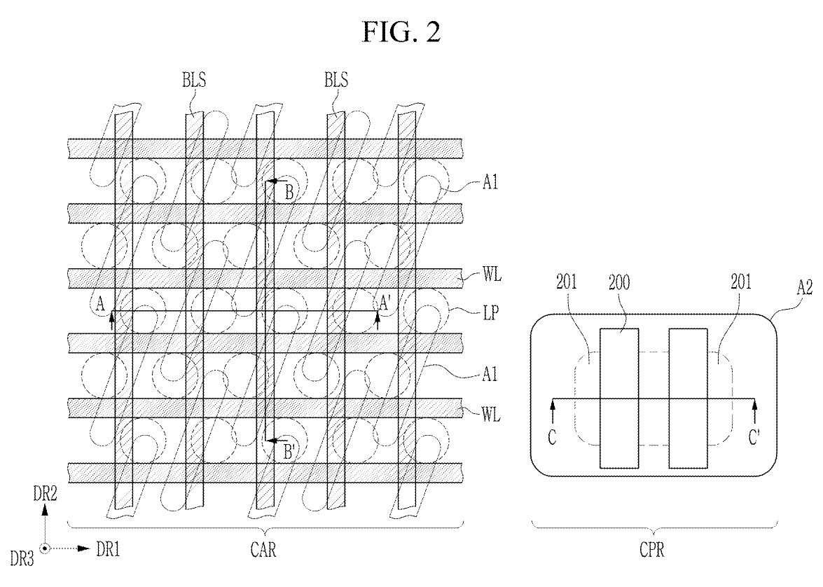

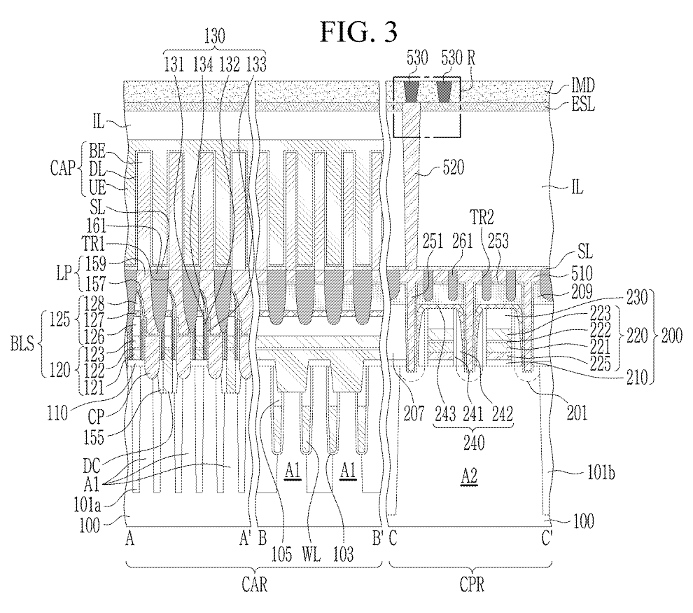

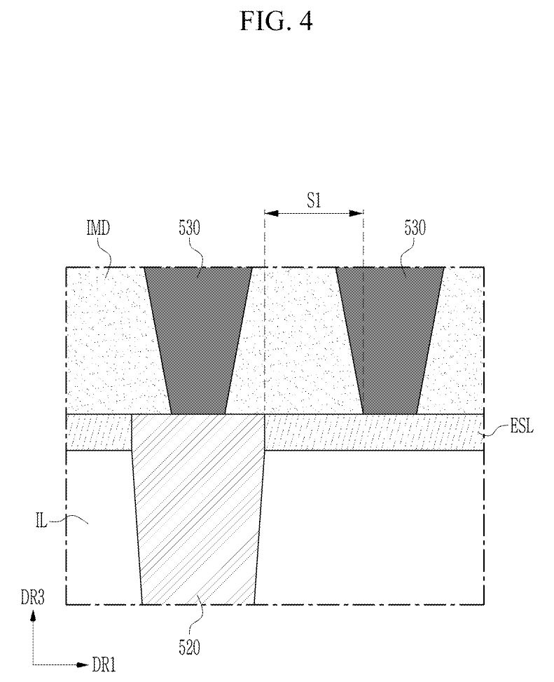

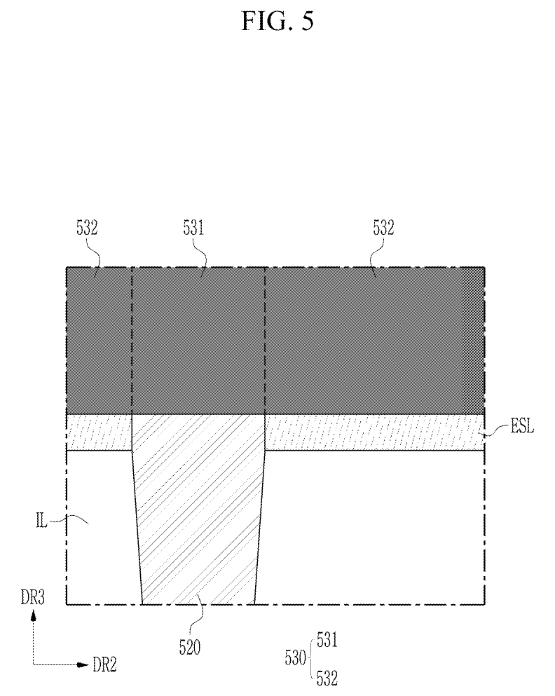

FIG. 1 is a plan view showing a semiconductor device according to an embodiment. FIG. 2 is a plan view showing a portion of a semiconductor device according to an embodiment. FIG. 3 is a cross-sectional view taken along lines A-A', B-B', and C-C' of FIG. 2. FIG. 4 is an enlarged cross-sectional view showing the R region of FIG. 3. FIG. 5 is an enlarged cross-sectional view showing a portion of a semiconductor device according to an embodiment. FIG. 5 is a cross-sectional view along a second direction DR2 and a third direction DR3 that enlarges a portion where a signal wiring 530 and a contact plug 520 of the semiconductor device are connected according to an embodiment.

As illustrated in FIG. 1, the semiconductor device according to an embodiment includes a substrate 100 including a cell array region CAR and a core/periphery region CPR. The core/periphery region CPR may be located around the cell array region CAR and may include a core region COR and a peripheral circuit region PER.

The substrate 100 may include a plurality of cell array regions CAR, and the plurality of cell array regions CAR may be arranged in a matrix form along a first direction DR1 and a second direction DR2. The second direction DR2 may intersect the first direction DR1. The second direction DR2 may intersect perpendicularly with the first direction DR1. Each of the plurality of cell array regions CAR may have a rectangular shape including two sides parallel along the first direction DR1 and two sides parallel along the second direction DR2. The plurality of cell array regions CAR may be spaced apart from each other, and the core region COR may be located between the plurality of cell array regions CAR. Each cell array region CAR may be surrounded by the core region COR. The core region COR may have a mesh shape in a plan view.

The peripheral circuit region PER may be located on one side of the plurality of cell array regions CAR and the core region COR. Although the plurality of cell array regions CAR and the core region COR are depicted as being located only on the left side of the peripheral circuit region PER, the plurality of cell array regions CAR and the core region COR may also be located on the right side of the peripheral circuit region PER. The plurality of cell array regions CAR may be gathered together to form a bank, and a plurality of banks may be arranged along the second direction DR2 on both sides of the peripheral circuit region PER.

The arrangement, shape, etc. of the cell array region CAR, core region COR, and peripheral circuit region PER have been described above, but this is only one example and is not limited thereto, and may be changed in various ways.

A memory cell may be located on each of the plurality of cell array regions CAR. In each cell array region CAR, at least one of a memory cell of a volatile memory device and a memory cell of a non-volatile memory device may be located. For example, cell transistors such as dynamic random access memory (DRAM) and flash memory may be located on the cell array region CAR. In each cell array region CAR, the plurality of unit memory cells may be positioned and store information. A unit memory cell may include at least one transistor and at least one capacitor.

The core region COR and peripheral circuit region PER may include driving circuits that generate signals capable of driving memory cells located on the cell array region CAR and wiring that transmits these signals. For example, in the core region COR, a sense amplifier, a sub word line driver, etc may be positioned. In the peripheral circuit region PER, a row decoder, a column decoder, etc may be positioned.

The semiconductor device according to an embodiment may include a transistor as a driving circuit for driving a memory cell. For example, the semiconductor device according to an embodiment may include a PMOS transistor, an NMOS transistor, and the like. In this way, the transistors that constitutes the driving circuit may be located on the core/periphery region CPR.

As illustrated in FIGS. 2 and 3, the semiconductor device according to an embodiment includes the substrate 100 including the cell array region CAR and the core/periphery region CPR. The core/periphery region CPR may include the core region COR and the peripheral circuit region PER.

A first device isolation layer 101a defining first active regions A1 may be positioned on the cell array region CAR of the substrate 100. The substrate 100 may be a semiconductor substrate including silicon, germanium or silicon-germanium.

The first active regions A1 may be provided on an upper portion of the substrate 100. The first active regions A1 may be formed by patterning the upper portion of the substrate 100. The first active regions A1 may be two-dimensionally arranged along the first direction DR1 and the second direction DR2. The first active region A1 may have a rectangular shape (or bar shape). The first active region A1 may have a longitudinal axis in a diagonal direction with respect to the first direction DR1 and the second direction DR2. The width of the first active region A1 may decrease as it gets farther away from a bottom surface of the substrate 100 in a cross-sectional view. For example, the first active region A1 may have a width that narrows in a direction perpendicular to an upper surface of the substrate 100 (e.g., in a third direction (DR3)).

Word lines WL may be arranged within the substrate 100. The word lines WL may be arranged along the second direction DR2. The word line WL may extend in the first direction DR1 in a plan view and cross the first active regions A1 and the first device isolation layer 101a. A cell gate insulating layer 103 may be interposed between the word lines WL and the substrate 100.

Specifically, gate recess regions may be formed within the first active regions A1 and the first device isolation layer 101a. The cell gate insulating layer 103 may conformally cover the inner walls of the gate recess regions. The word lines WL may be spaced apart from the first active regions A1 and the first device isolation layer 101a with the cell gate insulating layer 103 therebetween. An upper surfaces of the word lines WL may be located below the upper surface of the substrate 100. A gate capping layer 105 may be arranged on the upper surface of the word lines WL to fill the remainder of the gate recess regions. The level of an upper surface of the gate capping layer 105 may be substantially the same as the level of the upper surface of the substrate 100.

Bit line structures BLS may extend in the second direction DR2 across the first active regions A1 in a plan view. Bit line structures BLS may intersect and be insulated from word lines WL. The bit line structures BLS may include a bit line 120 and a bit line capping pattern 125 on the bit line 120.

The bit line 120 may include a polysilicon pattern 121, a silicide pattern 122, and a metal pattern 123 that are sequentially stacked. A lower insulating layer 110 may be interposed between the polysilicon pattern 121 and the substrate 100. A bit line contact pattern DC may be located between the bit line 120 and the first active region A1. The bit line 120 may be electrically connected to the first active region A1 through the bit line contact pattern DC. A lower surface of the bit line contact pattern DC may be located below the upper surface of the substrate 100 and above the upper surfaces of the word lines WL. The bit line contact pattern DC may be formed within the substrate 100 and locally positioned within a recessed region exposing an upper surface of the first active region A1. The recessed region may have an elliptical shape in a plan view, and a width of the recessed region in the short axis direction may be greater than a width of the bit line structures BLS.

A bit line capping pattern 125 may be positioned on the metal pattern 123 of the bit line 120. The bit line capping pattern 125 may include a first capping pattern 126, a second capping pattern 127, and a third capping pattern 128 that are sequentially stacked.

A bit line contact spacer 155 may fill the remainder of the recessed region where the bit line contact pattern DC is formed. For example, the bit line contact spacer 155 may cover both sides of the bit line contact pattern DC. As another example, the bit line contact spacer 155 may surround the sides of the bit line contact pattern DC within the recessed region. The bit line contact spacer 155 may be formed of an insulating material having etch selectivity with respect to the lower insulating layer 110. For example, the bit line contact spacer 155 may include a silicon oxide film, a silicon nitride film, and/or a silicon oxynitride film, and may be formed of a multilayer film. According to embodiments, an upper surface of the bit line contact spacer 155 may be positioned at substantially the same level as an upper surface of the lower insulating layer 110.

Storage contacts CP may be positioned between sidewalls of bit line structures BLS. Storage contacts CP may be arranged along the first direction DR1 on the sidewalls of the bit line structures BLS. Each of the storage contacts CP may be arranged between word lines WL and between bit line structures BLS in a plan view. Each of the storage contacts CP may be connected to the substrate 100 between two adjacent bit lines 120 among the bit lines 120. The storage contact CP may be electrically connected to the first active region A1 of the substrate 100. The storage contact CP may include, for example, doped polysilicon.

A lower end of the storage contact CP may be located at a level lower than the upper surface of the substrate 100 and may be located at a level higher than a lower end of the bit line contact pattern DC. An upper surface of the storage contact CP may be located below a lower surface of the bit line capping pattern 125 of the bit line structure BLS. The storage contact CP may be insulated from the bit line contact pattern DC by the bit line contact spacer 155.

A landing pad LP may be positioned on the storage contact CP. The landing pad LP may be electrically connected to the first active region A1 of the substrate 100 through the storage contact CP. An upper surface of the landing pad LP may be located above the upper surfaces of the bit line structures BLS, and a lower surface of the landing pad LP may be located below the upper surfaces of the bit line structures BLS. For example, a lower surface of the landing pad LP may be positioned lower than an upper surface of the metal pattern 123 of the bit line 120. The landing pad LP may include a sequentially laminated barrier layer 157 and a pad metal pattern 159. According to embodiments, a contact silicide pattern may be provided between the storage contact CP and the landing pad LP.

A spacer structure 130 may be provided between the bit line structures BLS and the storage contacts CP. The spacer structure 130 may extend in the second direction DR2 along the sidewalls of the bit line structures BLS. The spacer structure 130 may include a first spacer 131, a second spacer 132, a third spacer 133, and a fourth spacer 134. The first spacer 131 may be positioned directly on the sidewall of the bit line structures BLS. The second spacer 132 may be positioned between the first spacer 131 and the storage contact CP. The third spacer 133 may be positioned between the second spacer 132 and the storage contact CP. The second spacer 132 may be positioned between the first spacer 131 and the third spacer 133. The first spacer 131 and the third spacer 133 may include an insulating material having etch selectivity with respect to the lower insulating layer 110.

The second spacer 132 may include an insulating material having a lower dielectric constant than the first spacer 131 and the third spacer 133. For example, the first spacer 131 and the third spacer 133 may include a silicon nitride film, and the second spacer 132 may include a silicon oxide film. As another example, the second spacer 132 may include an air gap. That is, the second spacer 132 may be an air spacer defined between the side walls of the first spacer 131 and the third spacer 133. The fourth spacer 134 may be provided on a side surface of the first spacer 131 and on an upper surface of the second spacer 132. The fourth spacer 134 may surround a lower portion of the landing pad LP. The fourth spacer 134 may have a ring shape in a plan view.

An insulating pattern 161 may fill the space between landing pads LP. The insulating pattern 161 may surround the side walls of the landing pads LP. The insulating pattern 161 may be provided within a first trench TR1 between the side walls of the landing pads LP, as illustrated in FIG. 3. The first trench TR1 may be a node isolation trench that electrically isolates each of the landing pads LP. The landing pads LP may be spaced apart from each other with the first trench TR1 between them. The first trench TR1 may have an inner surface defined by surfaces of landing pads LP, bit line capping patterns 125, and spacer structures 130. For example, the insulating pattern 161 may include silicon nitride.

Capacitors CAP may be provided on the landing pads LP. The capacitors CAP may be electrically connected to the landing pads LP, respectively. Each of the capacitors CAP may include a lower electrode BE, an upper electrode UE, and a dielectric layer DL therebetween. Each of the lower electrode BE and the upper electrode UE may include, for example, one of titanium, tantalum, tungsten, copper, and aluminum.

The lower electrode BE and the upper electrode UE may each include doped silicon, Ru, RuO, Pt, PtO, Ir, IrO, SRO (SrRuO), BSRO ((Ba,Sr)RuO), CRO (CaRuO), BaRuO, La(Sr,Co)O, Ti, TiN, W, WN, Ta, TaN, TiAlN, TiSiN, TaAlN, TaSiN, or a combination thereof. The dielectric layer DL may include, for example, hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or combinations thereof.

A gate stack 200 may be arranged on the substrate 100 of the core region COR. The gate stack 200 may extend in a direction parallel to the upper surface of the substrate 100. For example, the gate stack 200 may have a bar shape in a plan view. The gate stack 200 may be positioned on a second active region A2 formed on the upper portion of the substrate 100. The second active region A2 may be a region doped with n-type or p-type impurities and may be defined by a second device isolation layer 101b.

Impurity regions 201 may be formed on the upper portion of the substrate 100. The impurity regions 201 may include impurities of a different conductivity type from the impurities doped in the second active region A2. The impurity regions 201 may be a pair of source and drain regions that are electrically connected or separated depending on the voltage applied to the gate stack 200. The impurity regions 201 may be spaced apart from each other with the gate stack 200 between them. Each of the impurity regions 201 may be positioned adjacent to both sides of the gate stack 200. For example, the gate stack 200 and the impurity regions 201 may constitute a PMOS transistor, and the impurity regions 201 may be p-type impurity regions. The impurity regions 201 may include, for example, at least one of the elements boron (B), aluminum (Al), gallium (Ga), and indium (In). As another example, the gate stack 200 and the impurity regions 201 may constitute an NMOS transistor, and the impurity regions 201 may be n-type impurity regions. The impurity regions 201 may include, for example, at least one of the elements phosphorus (P), arsenic (As), and antimony (Sb).

The gate stack 200 may include a gate insulating layer 210, a gate electrode 220, and a gate capping pattern 230. The gate insulating layer 210 may be interposed between the upper surface of the substrate 100 and the gate electrode 220. The gate capping pattern 230 may be positioned on an upper surface of the gate electrode 220.

The gate insulating layer 210 may include a dielectric. According to embodiments, the gate insulating layer 210 may include a first dielectric layer and a second dielectric layer on the first dielectric layer. The first dielectric layer may have a lower dielectric constant than the second dielectric layer. The first dielectric layer may include, for example, one of a silicon oxide film and a silicon oxynitride film. The second dielectric layer may include a high-k material having a higher dielectric constant than the silicon oxide film and/or the silicon oxynitride film. The second dielectric layer may include one of an oxide, nitride, silicide, or oxynitride, for example, including one of hafnium (Hf), aluminum (Al), zirconium (Zr), and lanthanum (La).

The gate electrode 220 may include a work function control layer 225, a first conductive layer 221, a second conductive layer 222, and a third conductive layer 223 that are sequentially laminated. The work function control layer 225 may adjust the threshold voltage of the transistor. According to embodiments, the work function control layer 225 may have a thicker thickness than the gate insulating layer 210. The work function control layer 225 may include at least one of a p-type metal layer and an n-type metal layer. The work function control layer 225 may include, for example, at least one of Ti, Ta, Al, Ni, Co, La, Pd, Nb, Mo, Hf, Ir, Ru, Pt, Yb, Dy, Er, Pd, TiAl, HfSiMo, TiN, WN, TaN, RuN, MoN, TiAlN, TaC, TiC, and TaC. The work function control layer 225 may further include, for example, at least one of La/TiN, Mg/TiN, or Sr/TiN.

The first conductive layer 221 may include a doped semiconductor material. The first conductive layer 221 may include, for example, polysilicon. The first conductive layer 221 may be doped with, for example, a p-type dopant.

The second conductive layer 222 may be located between the first conductive layer 221 and the third conductive layer 223. The second conductive layer 222 may have a thinner thickness than the first conductive layer 221 and the third conductive layer 223. The second conductive layer 222 may include silicide formed at the interface between the first conductive layer 221 and the third conductive layer 223. The second conductive layer 222 may include, for example, one of titanium silicide, cobalt silicide, nickel silicide, tungsten silicide, platinum silicide, and molybdenum silicide.

The third conductive layer 223 may include a metal material. The third conductive layer 223 may include, for example, at least one of W, Ti, or Ta.

The gate capping pattern 230 may be positioned on the upper surface of the gate electrode 220. The gate capping pattern 230 is formed to cover an upper surface of the third conductive layer 223 to protect the gate electrode 220. The gate capping pattern 230 may include an insulating material. The gate capping pattern 230 may include, for example, silicon nitride.

A gate spacer structure 240 may be positioned on side surfaces of the gate stack 200. The gate spacer structure 240 may include a first gate spacer 241, a second gate spacer 242, and a third gate spacer 243.

A first gate spacer 241 may be positioned on the side surface of the gate stack 200. The first gate spacer 241 may extend vertically along the side surfaces of the gate stack 200. The first gate spacer 241 may have a lower oxygen element content ratio than the second gate spacer 242. The first gate spacer 241 may have a first dielectric constant, and the first dielectric constant may have a value in the range of 6.5 to 7.5. The first gate spacer 241 may include the first dielectric layer of the gate insulating layer 210 and a material having etch selectivity. The first gate spacer 241 may include, for example, silicon nitride. An upper surface of the first gate spacer 241 may be coplanar with an upper surface of the gate capping pattern 230. The first gate spacer 241 may be directly positioned on a side surface of the gate electrode 220 and a side surface of the gate capping pattern 230.

The second gate spacer 242 may be positioned on the first gate spacer 241. The second gate spacer 242 may have a larger width than the first gate spacer 241. The width of the second gate spacer 242 may become smaller as it gets farther away from the upper surface of the substrate 100. The second gate spacer 242 may include, for example, silicon oxide.

The third gate spacer 243 may be provided on the second gate spacer 242. The third gate spacer 243 may extend onto an upper surface of the gate stack 200 to cover the upper surface of the first gate spacer 241 and the upper surface of the gate capping pattern 230. The third gate spacer 243 may extend onto the upper surface of the substrate 100.

A first interlayer insulating layer 207 may be formed on the substrate 100. The first interlayer insulating layer 207 may cover sidewalls of the gate spacer structure 240 and may not cover an upper surface of the gate spacer structure 240. An upper surface of the first interlayer insulating layer 207 may be coplanar with an upper surface of the third gate spacer 243. The first interlayer insulating layer 207 may include an HDP oxide film or a silicon oxide film formed by a FCVD (flowable CVD) method. A second interlayer insulating layer 209 may be positioned on the first interlayer insulating layer 207. A lower surface of the second interlayer insulating layer 209 may cover the upper surface of the third gate spacer 243. The second interlayer insulating layer 209 may include silicon nitride.

Circuit wiring 510 may be located on the second interlayer insulating layer 209. The circuit wiring 510 located on the core/periphery region CPR may be located in the same layer as the pad metal pattern 159 of the landing pad LP located on the cell array region CAR. The circuit wiring 510 may be formed in the same process using the same material as the pad metal pattern 159. The circuit wiring 510 may be connected to impurity regions 201 through contact vias 251. The contact via 251 and the circuit wiring 510 may include, for example, at least one of copper (Cu), tungsten (W), aluminum (Al), tantalum (Ta), and titanium (Ti). The contact via 251 may be connected to the substrate 100 by penetrating the first interlayer insulating layer 207 and the second interlayer insulating layer 209. According to embodiments, a lower end of the contact via 251 may be located at a level lower than the upper surface of the substrate 100. Contact vias 251 may electrically connect the circuit wiring 510 and the impurity regions 201.

A contact barrier layer 253 may cover a surface of the circuit wiring 510 and the contact via 251. The contact barrier layer 253 may be provided between a lower surface of the circuit wiring 510 and the second interlayer insulating layer 209. The contact barrier layer 253 may be provided on side surfaces and lower surfaces of the contact vias 251. The contact barrier layer 253 may include a metal nitride. The contact barrier layer 253 may include, for example, one of titanium nitride (TiN0), tantalum nitride (TaN0), and tungsten nitride (WN).

A second trench TR2 may be formed between the circuit wirings 510. The second trench TR2 may be formed between the side walls of the circuit wirings 510 and may be formed to a predetermined depth from an upper surface of the second interlayer insulating layer 209. A lower end of the second trench TR2 may be located at a higher level than the upper surface of the gate capping pattern 230.

For example, the second trench TR2 may be positioned to vertically overlap the gate stack 200 or may be positioned to vertically overlap the second device isolation layer 101b between the gate stacks 200.

A wiring insulating pattern 261 may fill the second trench TR2. For example, the wiring insulating pattern 261 may include silicon nitride.

A lower etch stop layer SL covering the insulating pattern 161, the wiring insulating pattern 261, and the circuit wirings 510 may be provided. An insulating layer IL may be provided on the lower etch stop film SL. The insulating layer IL may be positioned on the cell array region CAR and core/periphery region CPR of the substrate 100. The insulating layer IL may cover capacitors CAP on the cell array region CAR. The insulating layer IL may cover the circuit wirings 510 on the core/periphery region CPR.

A contact plug 520 that penetrates the insulating layer IL and the lower etch stop layer SL and is connected to the circuit wirings 510 may be provided. A lower end of the contact plug 520 may contact an upper surface of the circuit wiring 510. A lower surface of the contact plug 520 may come into contact with the upper surface of the circuit wiring 510.

A signal wiring 530 may be located on the insulating layer IL. The signal wiring 530 may be located on the contact plug 520. The signal wiring 530 may be spaced apart from the circuit wiring 510 in a direction perpendicular to the upper surface of the substrate 100. The contact plug 520 may connect between the circuit wiring 510 and the signal wiring 530. The signal wiring 530 may be electrically connected to the contact plug 520. The signal wiring 530 may be electrically connected to the circuit wiring 510 through the contact plug 520. The circuit wiring 510 may receive a predetermined signal through signal wiring 530.

An wiring insulating layer IMD may be positioned on the insulating layer IL. The wiring insulating layer IMD may cover a side surface of the signal wiring 530. On the insulating layer IL, a plurality of signal wirings 530 may be arranged in a parallel direction on the upper surface of the substrate 100. The wiring insulating layer IMD may be positioned between the plurality of signal wirings 530. The plurality of signal wirings 530 may be insulated by the wire insulating layer IMD.

An etch stop layer ESL may be located between the insulating layer IL and the wiring insulating layer IMD. The etch stop layer ESL may serve to prevent etching during a process of planarizing a material layer forming a contact plug 520 after depositing the layer (e.g., a chemical mechanical polishing (CMP) process). Additionally, the etch stop layer ESL may serve to prevent etching during the process of etching a trench in which the signal wiring 530 is to be formed. The etch stop layer ESL may include a material having etching selectivity with respect to the contact plug 520. The etch stop layer ESL may include a material having etching selectivity with respect to the wiring insulating layer IMD. Additionally, the etch stop layer ESL may include a material having etching selectivity with respect to the insulating layer IL. The etch stop layer ESL may include an insulating material. For example, the etch stop layer ESL may include, but is not limited to, SiCN, SiON, AlN, AlO, SiN, or combinations thereof. The etch stop layer ESL may be composed of a single layer or the plurality of layers. For example, the etch stop layer ESL thickness may be less than 700 Å (Angstroms).

Below, the arrangement of the contact plug 520, signal wiring 530, and etch stop layer ESL is described in more detail.

As shown in FIGS. 4 and 5, the contact plug 520 may penetrate the insulating layer IL. The signal wiring 530 and the wire insulating layer IMD covering the side surface of the signal wiring 530 may be positioned on the insulating layer IL. The etch stop layer ESL may be positioned between the insulating layer IL and the wiring insulating layer IMD. The contact plug 520 may further penetrate the etch stop layer ESL. The etch stop layer ESL includes an opening, and an upper portion of the contact plug 520 may be positioned within the opening of the etch stop layer ESL.

The etch stop layer ESL may be positioned on a side surface of the contact plug 520 and may not be positioned on an upper surface of the contact plug 520. The etch stop layer ESL may overlap the contact plug 520 in a direction parallel to the upper surface of the substrate 100 (e.g., in the first direction DR1), and may not overlap in a direction perpendicular to the upper surface of the substrate 100 (e.g., in the third direction DR3). The etch stop layer ESL may be in contact with the side surface of the contact plug 520 and may not be in contact with the upper surface of the contact plug 520.

The upper surface of the contact plug 520 may come into contact with the signal wiring 530 and the wiring insulating layer IMD. The approximate center of the upper surface of the contact plug 520 may be in contact with the signal wiring 530, but is not limited thereto. The remaining portion of the upper surface of the contact plug 520 that does not come into contact with the signal wiring 530 may come into contact with the wiring insulating layer IMD.

As illustrated, a width of a lower surface of the signal wiring 530 may be smaller than a width of the upper surface of the contact plug 520, but is not limited thereto. The width of the lower surface of the signal wiring 530 may be equal to or greater than a width of the upper surface of the contact plug 520. In this case, the upper surface of the contact plug 520 may be in contact with the signal wiring 530 and may not be in contact with the wiring insulating layer IMD. The width of the lower surface of the signal wiring 530 and the width of the upper surface of the contact plug 520 may mean the length along the first direction DR1.

The side surface of the contact plug 520 may be in contact with an etch stop layer ESL and an insulating layer IL. A side surface of an upper portion of the contact plug 520 may be in contact with the etch stop layer ESL, and a side surface of a lower portion of the contact plug 520 may be in contact with the insulating layer IL. The lower portion of the contact plug 520 may refer to a portion of the contact plug 520 located below an etch stop layer ESL. The contact plug 520 may have a pillar shape extending in a direction perpendicular to the upper surface of the substrate 100. The contact plug 520 may have a polygonal shape such as a circle, an oval, or a square in a plan view. The etch stop layer ESL may surround an outer surface of the upper portion of the contact plug 520. The insulating layer IL may surround an outer surface of the lower portion of the contact plug 520.

An upper surface of the etch stop layer ESL and the upper surface of the contact plug 520 may be positioned at substantially the same level. The upper surface of the etch stop layer ESL and the upper surface of the contact plug 520 may form a coplanar surface.

The wiring insulating layer IMD may be positioned on the contact plug 520 and the etch stop layer ESL. The wiring insulating layer IMD may cover the upper surface of the contact plug 520 and the upper surface of the etch stop layer ESL.

The signal wiring 530 may be located on the contact plug 520 and the etch stop layer ESL. The signal wiring 530 may penetrate the wiring insulating layer IMD and come into contact with the contact plug 520 and the etch stop layer ESL. A lower surface of the signal wiring 530 may be in contact with the upper surface of the contact plug 520 and the upper surface of the etch stop layer ESL.

The plurality of signal wirings 530 may be arranged spaced apart in the first direction DR1 on the contact plug 520 and the etch stop layer ESL. Each of the plurality of signal wirings 530 may extend in the second direction DR2 intersecting the first direction DR1. The first direction DR1 and the second direction DR2 are directions parallel to the upper surface of the substrate 100. For example, the second direction DR2 may be a direction perpendicular to the first direction DR1.

As illustrated in FIG. 5, each of the plurality of signal wirings 530 may include a first portion 531 that comes into contact with the contact plug 520 and a second portion 532 that is the remaining portion excluding the first portion 531. In an embodiment, the second portion 532 of the signal wiring 530 may be in contact with the etch stop layer ESL. However, the examples are not limited to this. Another layer may be positioned between the second portion 532 of the signal wiring 530 and the etch stop layer ESL.

The etch stop layer ESL may be positioned between the signal wiring 530 and the insulating layer IL. The etch stop layer ESL may be positioned between the second portion 532 of the signal wiring 530 and the insulating layer IL.

The signal wiring 530 may not penetrate the etch stop layer ESL. The lower surface of the signal wiring 530 may be located at a higher level than the lower surface of the etch stop layer ESL. In the embodiment illustrated in FIGS. 4 and 5, the lower surface of the signal wiring 530 may be positioned at the same level as the upper surface of the etch stop layer ESL. A lower surface of the second portion 532 of the signal wiring 530 may be located at the same level as the upper surface of the etch stop layer ESL. The lower surface of the second portion 532 of the signal wiring 530 may be in contact with the upper surface of the etch stop layer ESL.

A lower surface of the first portion 531 of the signal wiring 530 may be located at the same level as the upper surface of the etch stop layer ESL. As described above, the upper surface of the etch stop layer ESL and the upper surface of the contact plug 520 may be located at the same level. The lower surface of the first portion 531 of the signal wiring 530 may be positioned at the same level as the upper surface of the contact plug 520. The lower surface of the first portion 531 of the signal wiring 530 may be in contact with the upper surface of the contact plug 520.

The insulating layer IL may include a material having a higher dielectric constant than the wiring insulating layer IMD. As the signal wiring 530 does not penetrate the etch stop layer ESL, the insulating layer IL with a relatively high dielectric constant may not be recessed. In this case, the side surface of the signal wiring 530 may be covered by a wiring insulating layer IMD having a relatively low dielectric constant and may not be covered by an insulating layer IL having a relatively high dielectric constant. Accordingly, the dielectric constant between adjacent signal wiring 530 and between the signal wiring 530 and the adjacent contact plug 520 may be reduced. When the dielectric constant between adjacent signal wiring 530 and between the signal wiring 530 and the adjacent contact plug 520 decreases, the parasitic capacitance of the signal wiring 530 may be reduced. According to an embodiment, a semiconductor device may have a lower dielectric constant between adjacent signal wirings 530 and between a signal wiring 530 and an adjacent contact plug 520 than a comparative example in which the signal wiring 530 penetrates the etch stop layer ESL and a portion of the signal wiring 530 is positioned within the insulating layer IL, so that the parasitic capacitance of the signal wiring 530 may be reduced.

S1 of FIG. 4 may be defined as the minimum distance along the first direction DR1 from the contact plug 520 to the signal wiring 530 connected to the contact plug 520 and another signal wiring 530 adjacent thereto. The first direction DR1 may be a direction in which the plurality of signal wirings 530 are arranged. As S1 increases, the electric field received by the insulating layer located between adjacent signal wirings 530 and between the signal wirings 530 and the adjacent contact plugs 520 decreases, thereby preventing a short circuit between adjacent signal wirings 530 and between the signal wirings 530 and the adjacent contact plugs 520 and reducing leakage current.

A width of the signal wiring 530 may gradually decrease as it goes downward. The width of the lower surface of the signal wiring 530 may be the minimum width of the signal wiring 530. The width of the signal wiring 530 may mean the length along the first direction DR1. In various embodiments, the term “gradually” means that a change will occur at a moderate rate, opposed to an abrupt or sudden change, as understood by one of ordinary skill in the art.

In the embodiment illustrated in FIG. 4, the adjacent signal wiring 530 does not penetrate the etch stop layer ESL, and the lower surface of the adjacent signal wiring 530 may be positioned at a higher level than the lower surface of the etch stop layer ESL. A lower surface of the adjacent signal wiring 530 having the minimum width may be positioned at the same level as the upper surface of the contact plug 520. Accordingly, S1 may be a distance along the first direction DR1 from the upper surface of the contact plug 520 to the lower surface of the adjacent signal wiring 530 having the minimum width.

In a comparative example, an adjacent signal wiring 530 may penetrate the etch stop layer ESL, and a lower surface of the adjacent signal wiring 530 may be located at a lower level than the lower surface of the etch stop layer ESL. A portion of the adjacent signal wiring 530 that is wider than the lower surface of the adjacent signal wiring 530 may be positioned at the same level as the upper surface of the contact plug 520. Accordingly, S1 may be a distance along the first direction DR1 from the upper surface of the contact plug 520 to the portion of the adjacent signal wiring 530 that is wider than the lower surface of the adjacent signal wiring 530.

At the same level along the third direction DR3, as a width of the adjacent signal wiring 530 along the first direction DR1 becomes smaller, the distance along the first direction DR1, for example, S1, from the contact plug 520 to the adjacent signal wiring 530 may increase. In the semiconductor device according to an embodiment, the width of the portion of the adjacent signal wiring 530 positioned at the same level as the upper surface of the contact plug 520 may be smaller than the width of the portion of the adjacent signal wiring 530 positioned at the same level as the upper surface of the contact plug 520 in a semiconductor device according to the comparative example. Accordingly, the semiconductor device according to an embodiment may have S1 greater than that of the comparative example. According to an embodiment, since the minimum distance along the first direction DR1 from the contact plug 520 to the signal wiring 530 connected to the contact plug 520 and another adjacent signal wiring 530 is greater than that in the comparative example, the reliability of the semiconductor device may be increased by preventing short circuits between adjacent signal wirings 530 and between the signal wiring 530 and the adjacent contact plug 520 and reducing leakage current.

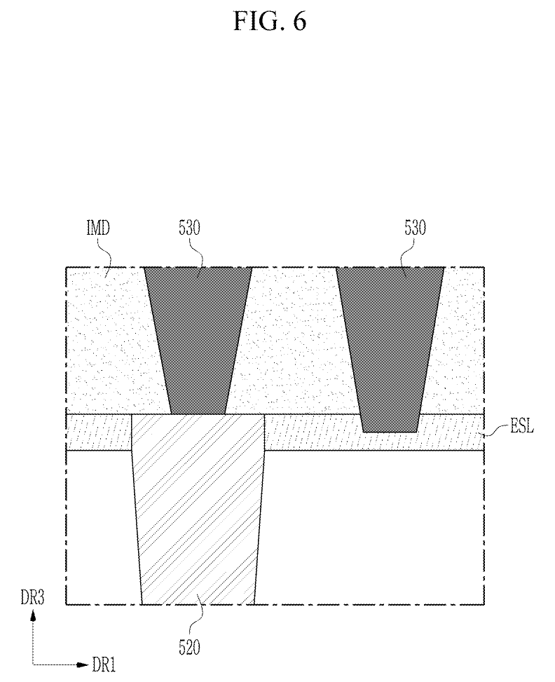

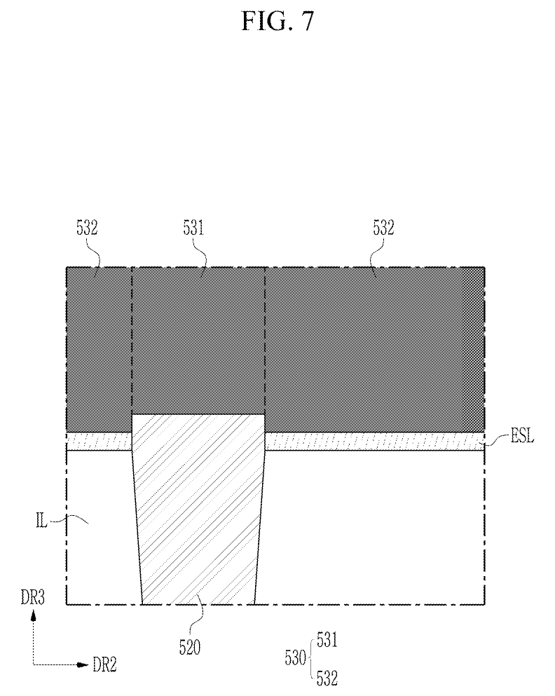

Hereinafter, a modified example of the semiconductor device according to the embodiments of FIGS. 4 and 5 will be described with reference to FIGS. 6 and 7.

FIG. 6 is an enlarged cross-sectional view of the R region in FIG. 3. FIG. 7 is an enlarged cross-sectional view showing a portion of a semiconductor device according to an embodiment. FIG. 7 is a cross-sectional view along the second direction DR2 and the third direction DR3 that enlarges a portion where the signal wiring 530 and the contact plug 520 of the semiconductor device are connected according to an embodiment. In the embodiment illustrated in FIGS. 6 and 7, the arrangement of the signal wiring 530 and the etch stop layer ESL may be partially different from the embodiment illustrated in FIGS. 4 and 5. In the embodiment illustrated in FIGS. 6 and 7, the same drawing reference numerals may be used for components that are identical or corresponding to those in the previous embodiments. Below, the differences from the embodiments illustrated in FIGS. 4 and 5 will be mainly explained, and any redundant explanations will be omitted or simplified.

As shown in FIGS. 6 and 7, the signal wiring 530 may recess an upper portion of the etch stop layer ESL. A lower portion of the signal wiring 530 may be surrounded by the etch stop layer ESL. A lower surface of the signal wiring 530 and a portion of a side surface of the signal wiring 530 adjacent to the lower surface of the signal wiring 530 may be in contact with the etch stop layer ESL.

For example, in a process of etching a trench in which the signal wiring 530 is to be formed, a portion of the etch stop layer ESL may be etched. However, even in this case, the etch stop layer ESL may not be completely etched. In an etching process, a material having a low etching selectivity of the wiring insulating layer IMD to the etch stop layer ESL and a high etching selectivity of the wiring insulating layer IMD to the contact plug 520 may be used. In this case, the speed at which the etch stop layer ESL is etched together with the wiring insulating layer IMD may be faster than the speed at which the contact plug 520 is etched. Accordingly, an upper surface of the contact plug 520 is hardly etched, and an upper surface of the etch stop layer ESL may be lower than the upper surface of the contact plug 520.

The signal wiring 530 may include a first portion 531 that comes into contact with the contact plug 520 and a second portion 532 that is the remaining portion excluding the first portion 531. A lower surface of the first portion 531 of the signal wiring 530 may be in contact with the upper surface of the contact plug 520. The lower surface of the first portion 531 of the signal wiring 530 may be positioned at the same level as the upper surface of the contact plug 520. The upper surface of the contact plug 520 may be located at the same level as the upper surface of the etch stop layer ESL. The upper surface of the contact plug 520 may be located at the same level as the uppermost surface of the etch stop layer ESL. The lower surface of the first portion 531 of the signal wiring 530 may be located at the same level as the uppermost surface of the etch stop layer ESL.

A lower surface of the second portion 532 of the signal wiring 530 may be in contact with the upper surface of the etch stop layer ESL. However, the examples are not limited to this. Another layer may be positioned between the second portion 532 of the signal wiring 530 and the etch stop layer ESL. The lower surface of the second portion 532 of the signal wiring 530 may be located at a lower level than the upper surface of the contact plug 520. The upper surface of the contact plug 520 may be located at the same level as the uppermost surface of the etch stop layer ESL. The lower surface of the second portion 532 of the signal wiring 530 may be located at a level lower than the uppermost surface of the etch stop layer ESL.

Unlike the embodiment illustrated in FIGS. 4 and 5, the signal wiring 530 may not only overlap the etch stop layer ESL in the third direction DR3, but also a portion of the signal wiring 530 may overlap the etch stop layer ESL in the first direction DR1.

In the embodiments illustrated in FIGS. 6 and 7, as in the embodiment illustrated in FIGS. 4 and 5, the signal wiring 530 may not penetrate the etch stop layer ESL. The etch stop layer ESL may be positioned between the signal wiring 530 and the insulating layer IL. The signal wiring 530 may be separated from the insulating layer IL by the etch stop layer ESL. Accordingly, the same effect as the embodiment shown in FIGS. 4 and 5 may be achieved. According to an embodiment, the semiconductor device may have a lower dielectric constant between adjacent signal wirings 530 and between the signal wiring 530 and an adjacent contact plug 520 than a comparative example in which the signal wiring 530 penetrates the etch stop layer ESL and a portion of the signal wiring 530 is positioned within the insulating layer IL, so that the parasitic capacitance of the signal wiring 530 may be reduced. In addition, the semiconductor device according to an embodiment may have a wider distance between adjacent signal wirings 530 and a longer distance between the signal wirings 530 and the adjacent contact plugs 520 than the comparative example in which the width of the portion of the adjacent signal wirings 530 where the signal wirings 530 penetrate the etch stop layer ESL and are positioned at the same level as the upper surface of the contact plugs 520. Accordingly, the semiconductor device according to an embodiment may prevent short circuits between adjacent signal wirings 530 and between the signal wirings 530 and the adjacent contact plugs 520, and may reduce leakage current, thereby increasing the reliability of the semiconductor device.

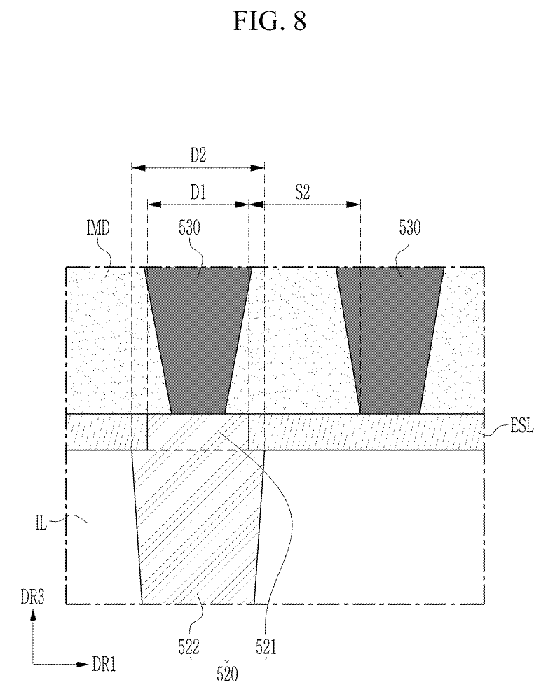

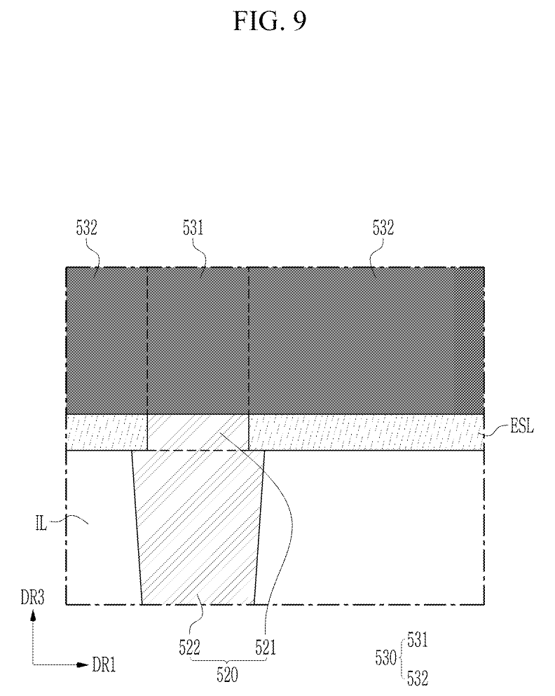

Hereinafter, a modified example of the semiconductor device according to the embodiments of FIGS. 4 and 5 will be described with reference to FIGS. 8 and 9.

FIG. 8 is an enlarged cross-sectional view of the R region in FIG. 3. FIG. 9 is an enlarged cross-sectional view showing a portion of a semiconductor device according to an embodiment. FIG. 9 is a cross-sectional view along the second direction DR2 and the third direction DR3 that enlarges a portion where the signal wiring 530 and the contact plug 520 of the semiconductor device are connected according to an embodiment. In the embodiment illustrated in FIGS. 8 and 9, the arrangement of the contact plug 520 and the etch stop layer ESL may be slightly different from the embodiment illustrated in FIGS. 4 and 5. In the embodiment illustrated in FIGS. 8 and 9, the same drawing reference numerals may be used for components that are identical or corresponding to those in the previous embodiments. Below, the differences from the embodiment illustrated in FIGS. 4 and 5 will be mainly explained, and any redundant explanations will be omitted or simplified.

As illustrated in FIGS. 8 and 9, the contact plug 520 may include a first portion 521 surrounded by the etch stop layer ESL and a second portion 522 extending from the first portion 521 toward the upper surface of the substrate 100. The second portion 522 of the contact plug 520 may be surrounded by the insulating layer IL. The first portion 521 of the contact plug 520 may be in contact with the etch stop layer ESL, and the second portion 522 of the contact plug 520 may be in contact with the insulating layer IL. A side surface of the first portion 521 of the contact plug 520 may come into contact with the etch stop layer ESL. A side surface of the second portion 522 of the contact plug 520 may come into contact with the insulating layer IL.

The etch stop layer ESL may not only overlap the contact plug 520 in a direction parallel to the upper surface of the substrate 100 (e.g., in the first direction (DR1)), but may also overlap the contact plug 520 in a direction perpendicular to the upper surface of the substrate 100 (e.g., in the third direction (DR3)). The etch stop layer ESL may overlap the first portion 521 of the contact plug 520 in a direction parallel to the upper surface of the substrate 100, and may overlap the second portion 522 of the contact plug 520 in a direction perpendicular to the upper surface of the substrate 100.

An upper surface of the first portion 521 of the contact plug 520 may be positioned at the same level as the upper surface of the etch stop layer ESL. The upper surface of the first portion 521 of the contact plug 520 may be coplanar with the upper surface of the etch stop layer ESL. An upper surface of the second portion 522 of the contact plug 520 may be positioned at the same level as a lower surface of the etch stop layer ESL. The upper surface of the second portion 522 of the contact plug 520 may be in contact with the lower surface of the etch stop layer ESL.

A diameter of the second portion 522 of the contact plug 520 may gradually decrease as it moves away from the first portion 521 of the contact plug 520. A diameter of the first portion 521 of the contact plug 520 may be smaller than the diameter of the second portion 522 of the contact plug 520 adjacent to the first portion 521 of the contact plug 520. The diameter D1 of the first portion 521 of the contact plug 520 may be smaller than the maximum diameter D2 of the second portion 522 of the contact plug 520. The second portion 522 of the contact plug 520 having the maximum diameter may be a portion most adjacent to the first portion 521 of the contact plug 520.

S1 of FIG. 4 and S2 of FIG. 8 may be defined as the distance along the first direction DR1 from the contact plug 520 to another signal wiring 530 adjacent to the signal wiring 530 connected to the contact plug 520, at the same level as the upper surface of the etch stop layer ESL. The first direction DR1 may be a direction in which the plurality of signal wirings 530 are arranged. As S1 and S2 become larger, short circuits between adjacent signal wirings 530 and between signal wirings 530 and adjacent contact plugs 520 may be prevented and leakage current may be reduced. Accordingly, the reliability of semiconductor devices may be increased.

As described above, in the embodiment illustrated in FIGS. 8 and 9, the diameter of the first portion 521 of the contact plug 520 surrounded by the etch stop layer ESL may be smaller than the maximum diameter of the second portion 522 of the contact plug 520 surrounded by the insulating layer IL.

In the embodiment illustrated in FIGS. 4 and 5, the diameter of a portion of the contact plug 520 surrounded by the etch stop layer ESL (e.g., corresponding to the first portion (521) of FIGS. 8 and 9) may be equal to the maximum diameter of a portion of the contact plug 520 surrounded by the insulating layer IL (e.g., corresponding to the second portion (522) of FIGS. 8 and 9).

For example, when the maximum diameter of the portion of the contact plug 520 surrounded by the insulating layer IL is the same in the embodiment illustrated in FIGS. 8 and 9 and the embodiment illustrated in FIGS. 4 and 5, the diameter of the contact plug 520 at the same level as the upper surface of the etch stop layer ESL may be smaller in the embodiment illustrated in FIGS. 8 and 9 than in the embodiment illustrated in FIGS. 4 and 5.

At the same level along the third direction DR3, as the diameter of the contact plug 520 decreases, the distance along the first direction DR1 from the signal wiring 530 adjacent to the contact plug 520 may increase. The diameter of the contact plug 520 at the same level as the upper surface of the etch stop layer ESL is smaller in the embodiment illustrated in FIGS. 8 and 9 than in the embodiment illustrated in FIGS. 4 and 5, so that S2 in FIG. 8 may be larger than S1 in FIG. 4. Accordingly, the width of the portion of the adjacent signal wiring 530 positioned at the same level as the upper surface of the contact plug 520 may be smaller than the width of the portion of the adjacent signal wiring 530 positioned at the same level as the upper surface of the contact plug 520 in the semiconductor device according to the comparative example. Accordingly, in the embodiment illustrated in FIGS. 8 and 9, the effect of increasing the reliability of the semiconductor device may be greater than in the embodiments illustrated in FIGS. 4 and 5.

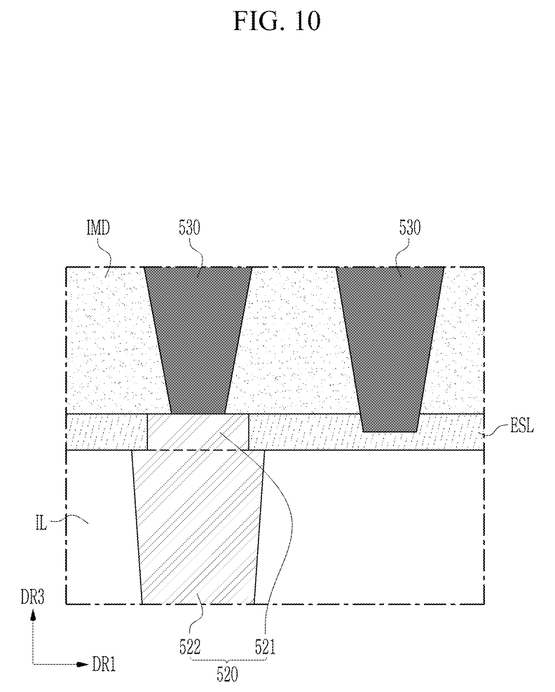

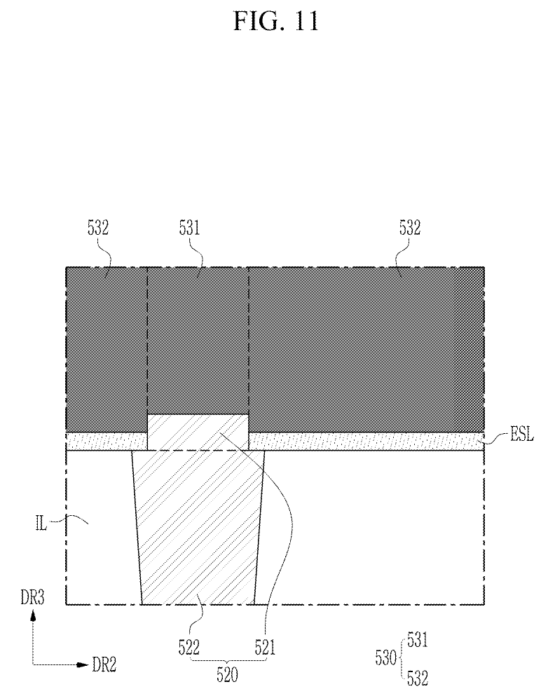

Hereinafter, a modified example of the semiconductor device according to the embodiments of FIGS. 8 and 9 will be described with reference to FIGS. 10 and 11.

FIG. 10 is an enlarged cross-sectional view of the R region in FIG. 3. FIG. 11 is an enlarged cross-sectional view showing a portion of a semiconductor device according to an embodiment. FIG. 11 is a cross-sectional view along the second direction DR2 and the third direction DR3 that enlarges a portion where the signal wiring 530 and the contact plug 520 of the semiconductor device are connected according to an embodiment. In the embodiments illustrated in FIGS. 10 and 11, the arrangement of the signal wiring 530 and the etch stop layer ESL may be partially different from the embodiments illustrated in FIGS. 8 and 9. In the embodiments illustrated in FIGS. 10 and 11, the same drawing reference numerals may be used for components that are identical or corresponding to those in the previous embodiments. Below, the differences from the embodiment illustrated in FIGS. 8 and 9 will be mainly explained, and any redundant explanations will be omitted or simplified.

As shown in FIGS. 10 and 11, the signal wiring 530 may recess an upper portion of the etch stop layer ESL. A lower portion of the signal wiring 530 may be surrounded by the etch stop layer ESL. A lower surface of the signal wiring 530 and a portion of the side surface of the signal wiring 530 adjacent to the lower surface of the signal wiring 530 may be in contact with the etch stop layer ESL.

For example, in a process of etching a trench in which the signal wiring 530 is to be formed, a portion of the etch stop layer ESL may be etched. However, even in this case, the etch stop layer ESL may not be completely etched. In an etching process, a material having a low etching selectivity of the wiring insulating layer IMD to the etch stop layer ESL and a high etching selectivity of the wiring insulating layer IMD to the contact plug 520 may be used. In this case, the speed at which the etch stop layer ESL is etched together with the wiring insulating layer IMD may be faster than the speed at which the contact plug 520 is etched. Accordingly, an upper surface of the contact plug 520 is hardly etched, and an upper surface of the etch stop layer ESL may be lower than the upper surface of the contact plug 520.

As in the embodiment illustrated in FIGS. 8 and 9, the signal wiring 530 may include the first portion 531 that comes into contact with the contact plug 520 and the second portion 532 that is the remaining portion excluding the first portion 531. A lower surface of the first portion 531 of the signal wiring 530 may be in contact with an upper surface of the first portion 521 of the contact plug 520. The lower surface of the first portion 531 of the signal wiring 530 may be positioned at the same level as the upper surface of the first portion 521 of the contact plug 520. The upper surface of the first portion 521 of the contact plug 520 may be positioned at the same level as the upper surface of the etch stop layer ESL. The upper surface of the first portion 521 of the contact plug 520 may be located at the same level as the uppermost surface of the etch stop layer ESL. The lower surface of the first portion 531 of the signal wiring 530 may be located at the same level as the upper surface of the etch stop layer ESL.

A lower surface of the second portion 532 of the signal wiring 530 may be in contact with the upper surface of the etch stop layer ESL. However, the examples are not limited to this. Another layer may be positioned between the second portion 532 of the signal wiring 530 and the etch stop layer ESL.

In the embodiment illustrated in FIGS. 8 and 9, the lower surface of the second portion 532 of the signal wiring 530 may be positioned at the same level as the uppermost surface of the etch stop layer ESL. In contrast, in the embodiment illustrated in FIGS. 10 and 11, the lower surface of the second portion 532 of the signal wiring 530 may be positioned at a level lower than the uppermost surface of the etch stop layer ESL. The upper surface of the first portion 521 of the contact plug 520 may be located at the same level as the uppermost surface of the etch stop layer ESL. The lower surface of the second portion 532 of the signal wiring 530 may be positioned at a lower level than the upper surface of the first portion 521 of the contact plug 520. The lower surface of the second portion 532 of the signal wiring 530 may be positioned at a higher level than an upper surface of the second portion 522 of the contact plug 520. The upper surface of the second portion 522 of the contact plug 520 may be positioned at the same level as the lower surface of the etch stop layer ESL. The lower surface of the second portion 532 of the signal wiring 530 may be located at a higher level than the lower surface of the etch stop layer ESL.

Unlike the embodiment illustrated in FIGS. 8 and 9, the signal wiring 530 may not only overlap the etch stop layer ESL in the third direction DR3, but also a portion of the signal wiring 530 may overlap the etch stop layer ESL in the first direction DR1.

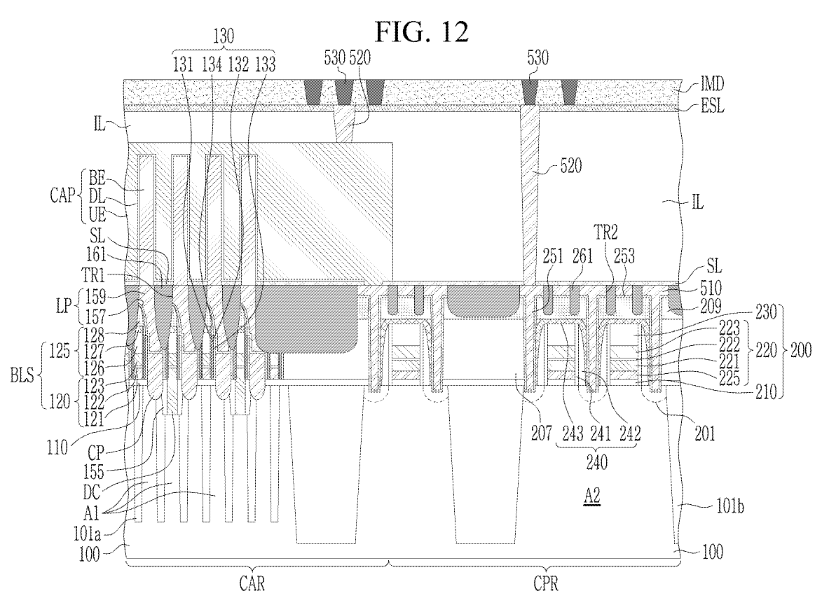

Hereinafter, a modified example of the embodiment illustrated in FIGS. 1 to 5 will be described with reference to FIG. 12.

FIG. 12 is a cross-sectional view showing a cell array region and a core/periphery region of a semiconductor device according to an embodiment. FIG. 12 may be a cross-sectional view along the first direction DR1 and the third direction DR3 of FIG. 2. In the embodiment illustrated in FIG. 12, the contact plug 520 may be connected to the capacitor CAP located on the cell array region CAR. In the embodiment illustrated in FIG. 12, the same drawing reference numerals may be used for components that are identical or corresponding to those in the previous embodiment. Below, the differences from the embodiments illustrated in FIGS. 1 to 5 will be mainly explained, and any redundant explanations will be omitted or simplified.

As illustrated in FIG. 12, the semiconductor device according to an embodiment may include a plurality of contact plugs 520. Each of the plurality of contact plugs 520 may electrically connect the signal wirings 530 and the circuit wirings 510 located on the core/periphery region CPR. As described above with reference to FIGS. 1 to 5, some of the plurality of contact plugs 520 may penetrate the insulating layer IL to connect between the signal wirings 530 and the circuit wirings 510 located on the core/periphery region CPR. Other parts of the plurality of contact plugs 520 may penetrate the insulating layer IL to connect between the signal wirings 530 and the upper electrode UE of the capacitor CAP located on the cell array region CAR. The upper electrode UE of the capacitor CAP may be electrically connected to the circuit wirings 510.

A lower end of the contact plug 520 may come into contact with an upper surface of the upper electrode UE of the capacitor CAP. A lower surface of the contact plug 520 may come into contact with the upper surface of the upper electrode UE of the capacitor CAP.

As illustrated in FIG. 12, the upper electrode UE extends further into the core/periphery region CPR, so that a portion of a lower surface of the upper electrode UE may come into contact with an upper surface of the circuit wiring 510. At this time, the upper electrode UE may penetrate the lower etch stop layer SL and come into contact with the upper surfaces of the circuit wirings 510. However, the examples are not limited to this. For example, the upper electrode UE may not be directly connected to the circuit wirings 510, but may be connected to the signal wirings 530 through the contact plugs 520, and may be connected to the circuit wirings 510 through the other contact plugs 520 connected to the signal wirings 530.

The arrangement of the contact plug 520 connected to the upper electrode UE of the capacitor CAP, signal wiring 530, and etch stop layer ESL may be applied identically to the contents described above with reference to FIGS. 1 to 5, and therefore, redundant descriptions are omitted.

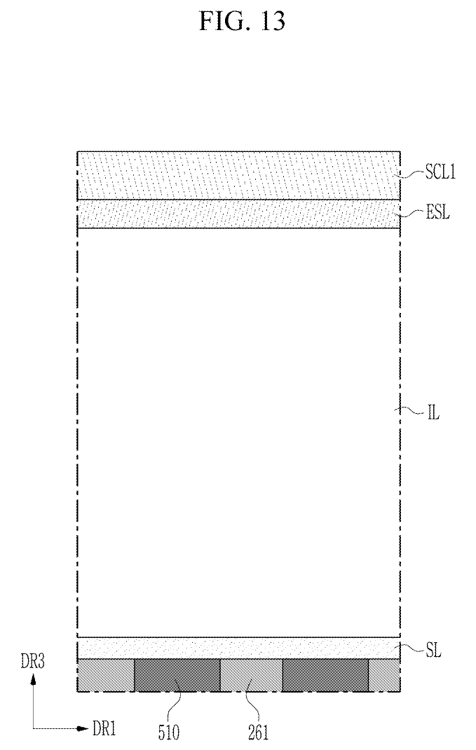

Hereinafter, a method for manufacturing a semiconductor device according to the embodiments shown in FIGS. 1 to 5 will be described with reference to FIGS. 13 to 22.

FIGS. 13 to 22 are cross-sectional views showing a portion of a manufacturing process of a semiconductor device according to an embodiment. FIGS. 13 to 22 are cross-sectional views centered on the circuit wiring 510, the signal wiring 530, the contact plug 520 connecting the circuit wiring 510 and the signal wiring 530, and the etch stop layer ESL.

Although not shown, the substrate 100 may be provided that includes the cell array region CAR and the core/periphery region CPR positioned around the cell array region CAR. the first device isolation layer 101a defining the first active regions A1 may be formed on the cell array region CAR of the substrate 100, and the second device isolation layer 101b defining the second active regions A2 may be formed on the core/periphery region CPR of the substrate 100. The first active regions A1 and the first device isolation layer 101a may be partially etched to form gate recess regions, and the cell gate insulating layer 103, the word line WL, and the gate capping layer 105 may be formed within the gate recess regions.

A preliminary gate insulating layer and a preliminary work function control layer may be formed on the core/periphery region CPR of the substrate 100. A first preliminary conductive layer, a second preliminary conductive layer, a third preliminary conductive layer, and a first preliminary insulating layer may be formed on the cell array region CAR and the core/periphery region CPR of the substrate 100. The gate stack 200 may be formed by performing a patterning process on the preliminary gate insulating layer, the preliminary work function control layer, the first preliminary conductive layer, the second preliminary conductive layer, the third preliminary conductive layer, and the first preliminary insulating layer located on the core/periphery region CPR of the substrate 100. Next, the first gate spacer 241 and the second gate spacer 242 may be formed on the sidewall of the gate stack 200.

A second preliminary insulating layer and a third preliminary insulating layer may be formed on the cell array region CAR and the core/periphery region CPR of the substrate 100. In the cell array region CAR, the first preliminary insulating layer, the second preliminary insulating layer, and the third preliminary insulating layer may be sequentially laminated. In the core/periphery region CPR, the second preliminary insulating layer may cover an upper surface of the substrate 100, a side surface of the second gate spacer 242, and an upper surface of the gate stack 200. The second preliminary insulating layer on the core/periphery region CPR may be partially etched in a subsequent process to form the third gate spacer 243. The first interlayer insulating layer 207 may be formed before the third preliminary insulating layer is formed in the core/periphery region CPR. The first interlayer insulating layer 207 may cover the third gate spacer 243. The first interlayer insulating layer 207 may have an upper surface positioned at the same level as an upper surface of the third gate spacer 243. The third preliminary insulating layer may be formed on the first interlayer insulating layer 207. The third preliminary insulating layer in the core/periphery region CPR may be partially etched in a subsequent process to form the second interlayer insulating layer 209.

A patterning process may be performed on the first preliminary conductive layer, the second preliminary conductive layer, the third preliminary conductive layer, the first preliminary insulating layer, the second preliminary insulating layer, and the third preliminary insulating layer located on the cell array region CAR of the substrate 100 to form the bit line structure BLS. Next, the first spacer 131, the second spacer 132, and the third spacer 133 may be sequentially formed on the sidewall of the bit line structure BLS. The bit line contact spacer 155 may be formed before forming the second spacer 132 and the third spacer 133.

A preliminary storage contacts may be formed between the sidewalls of the bit line structure BLS. Subsequently, an etching process may be performed to partially remove upper portions of the first spacer 131, the second spacer 132, and the third spacer 133 so that upper surfaces of the first spacer 131, the second spacer 132, and the third spacer 133 have a similar height to the preliminary storage contacts. The fourth spacer 134 may be formed to cover an upper side wall of the first spacer 131. Subsequently, upper portions of the preliminary storage contacts may be partially removed to form the storage contacts CP. An upper surfaces of the storage contacts CP may be positioned at a lower level than the upper surfaces of the second spacer 132 and the third spacer 133. The first spacer 131, the second spacer 132, the third spacer 133, and the fourth spacer 134 may form the spacer structure 130.

Next, contact holes may be formed that vertically penetrate the first interlayer insulating layer 207 and the second interlayer insulating layer 209 on the core/periphery region CPR of the substrate 100. As the contact holes are formed, an upper portion of the substrate 100 may be partially removed. Bottom surfaces of the contact holes may be located at a level lower than the uppermost surface of the substrate 100.

A preliminary barrier layer may be formed by performing a deposition process on the cell array region CAR and core/periphery region CPR of the substrate 100. The preliminary barrier layer may cover upper surfaces of the storage contacts CP, side surfaces of the spacer structures 130, and upper surfaces of the bit line structures BLS in the cell array region CAR. The preliminary barrier layer may cover an upper surface of the second interlayer insulating layer 209 and inner surfaces of the contact holes in the core/periphery region CPR.

A metal layer may be formed on the preliminary barrier layer. In the cell array region CAR, the metal layer may fill the space between the spacer structures 130 and extend over the upper surface of the bit line structure BLS. In the core/periphery region CPR, the metal layer may fill the interior of the contact holes and extend over the upper surface of the second interlayer insulating layer 209.

A patterning process may be performed on the preliminary barrier layer and the metal layer to form the first trench TR1 and the landing pad LP in the cell array region CAR. The landing pad LP may include the barrier layer 157 patterned with the preliminary barrier layer and the pad metal pattern 159 patterned with the metal layer. In addition, a patterning process may be performed on the preliminary barrier layer and the metal layer to form the second trench TR2, the circuit wiring 510, the contact via 251, and the contact barrier layer 253 in the core/periphery region CPR. The circuit wiring 510 may be connected to the impurity regions 201 through the contact vias 251. The contact barrier layer 253 may be provided between a lower surface of the circuit wiring 510 and the second interlayer insulating layer 209. The contact barrier layer 253 may be provided on side surfaces and a lower surface of the contact via 251.

A preliminary insulating pattern may be formed by performing a deposition process on the cell array region CAR and core/periphery region CPR of the substrate 100. The preliminary insulating pattern may fill the first trench TR1 in the cell array region CAR and cover an upper surface of the landing pad LP. The preliminary insulating pattern may fill the second trench TR2 in the core/periphery region CPR and cover an upper surface of the circuit wiring 510.

Next, a planarization process may be performed on the cell array region CAR and core/periphery region CPR of the substrate 100. The planarization process may proceed until the upper surface of the landing pad LP located on the cell array region CAR and the upper surface of the circuit wiring 510 located on the core/periphery region CPR are exposed. By the planarization process, the preliminary insulating pattern may be patterned in the cell array region CAR to form the insulating pattern 161. An upper surface of the insulating pattern 161 may be positioned at substantially the same level as an upper surface of the pad metal pattern 159. The preliminary insulating pattern may be patterned in the core/periphery region CPR to form the wiring insulating pattern 261. The upper surface of the wiring insulating pattern 261 may be positioned at substantially the same level as the upper surface of the circuit wiring 510.

The lower etch stop layer SL may be formed on the cell array region CAR and core/periphery region CPR of the substrate 100. A molding member including a material having etching selectivity with respect to the lower etch stop layer SL may be formed on the lower etch stop layer SL. A first mask may be provided on the molding member defining a region where the lower electrode BE is to be formed. The first mask may be used as an etching mask to sequentially etch a portion of the molding member and the lower etch stop layer SL to form electrode holes exposing the landing pads LP. The conductive material may be filled into the electrode holes to form the lower electrodes BE, and the first mask may be removed. Next, a second mask may be formed on the lower electrodes BE. The second mask may be used as an etching mask to etch the remainder of the molding member. Next, the dielectric layer DL and the upper electrode UE may be sequentially formed on the lower electrodes BE and the lower etch stop layer SL to form the capacitor CAP.

Next, as illustrated in FIG. 13, the insulating layer IL may be formed on the cell array region CAR and the core/periphery region CPR of the substrate 100. The insulating layer IL may cover the circuit wiring 510 positioned on the core/periphery region CPR. The insulating layer IL may cover the capacitor CAP positioned on the cell array region CAR.

The insulating layer IL may include a material having a relatively high dielectric constant. The insulating layer IL may include a material having a higher dielectric constant than the wiring insulating layer IMD to be formed in a subsequent process. The insulating layer IL may include, but is not limited to, TEOS.

Next, the etch stop layer ESL and a first sacrificial layer SCL1 may be sequentially formed on the insulating layer IL. According to an embodiment, the etch stop layer ESL may be first formed before forming a contact trench T1 corresponding to a region where the contact plug 520 is to be formed, and then the etch stop layer ESL may be etched together with the etching process for forming the contact trench T1. Thereafter, by filling the conductive layer within the contact trench T1 to form the contact plug 520, an upper surface of the contact plug 520 may be prevented from being covered by the etch stop layer ESL without a separate additional etching process for the etch stop layer ESL.

The etch stop layer ESL and the first sacrificial layer SCL1 may include an insulating material. For example, the etch stop layer ESL may include SiCN, SiON, AlN, AlO, SiN, or combinations thereof. The etch stop layer ESL may be composed of a single layer or the plurality of layers. The etch stop layer ESL and the first sacrificial layer SCL1 may include materials that having etching selectivity to each other. For example, the first sacrificial layer SCL1 may include SiCHO or SiO2. However, the materials of the etch stop layer ESL and the first sacrificial layer SCL1 are not limited thereto and may be variously changed.

For example, the etch stop layer ESL thickness may be less than 700 Å Angstroms. A thickness of the first sacrificial layer SCL1 may be 200 Å or more and 800 Å or less.

According to the illustrated embodiment, the first sacrificial layer SCL1 is formed on the etch stop layer ESL, but is not limited thereto. For example, the etch stop layer ESL may be formed on the insulating layer IL, and the first sacrificial layer SCL1 may not be formed. When the first sacrificial layer SCL1 is further formed, the risk of bridge defects occurring may be reduced by completely removing the first sacrificial layer SCL1 in a subsequent planarization process, and the surface step of the etch stop layer ESL after the planarization process may be reduced. When the first sacrificial layer SCL1 is further formed on the etch stop layer ESL, the etch stop layer ESL may be formed thinner.

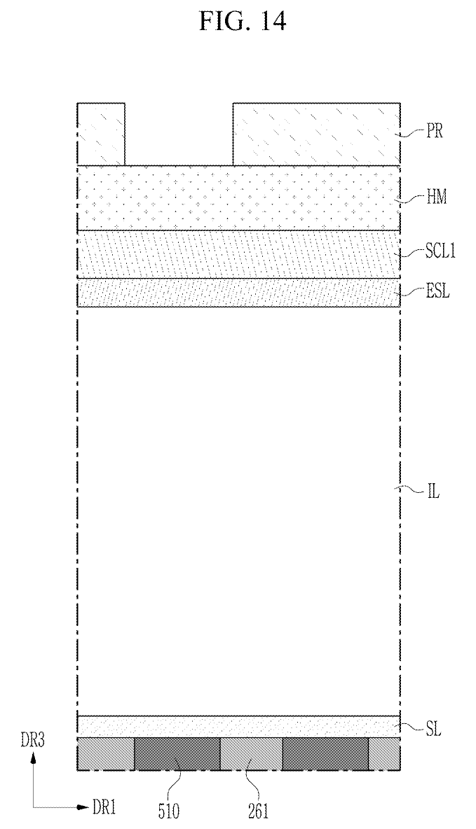

As illustrated in FIG. 14, a hard mask layer HM may be formed on the first sacrificial layer SCL1, and a photoresist pattern PR may be formed on the hard mask layer HM.

First, the hard mask layer HM and the photoresist layer are sequentially formed using a deposition process on the first sacrificial layer SCL1, and a photolithography process is performed on the photoresist layer to form a photoresist pattern PR defining a region where the contact plug 520 is to be formed.

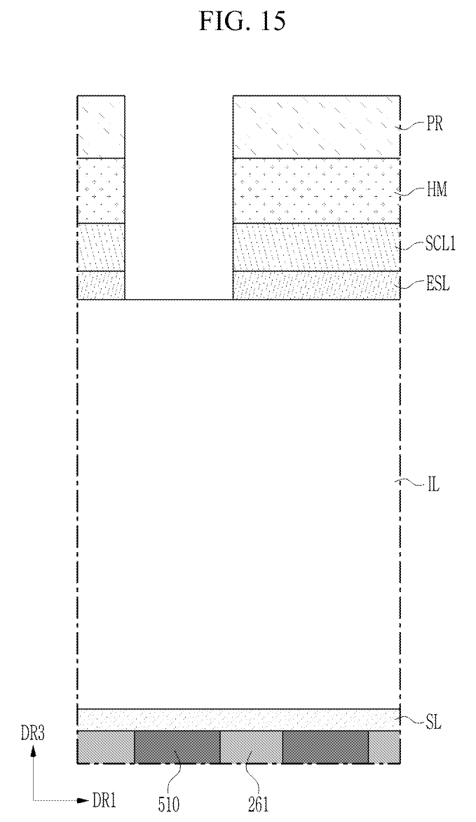

As illustrated in FIG. 15, an etching process may be performed using the photoresist pattern PR as an etching mask to pattern the hard mask layer HM, the first sacrificial layer SCL1, and the etching stop layer ESL.

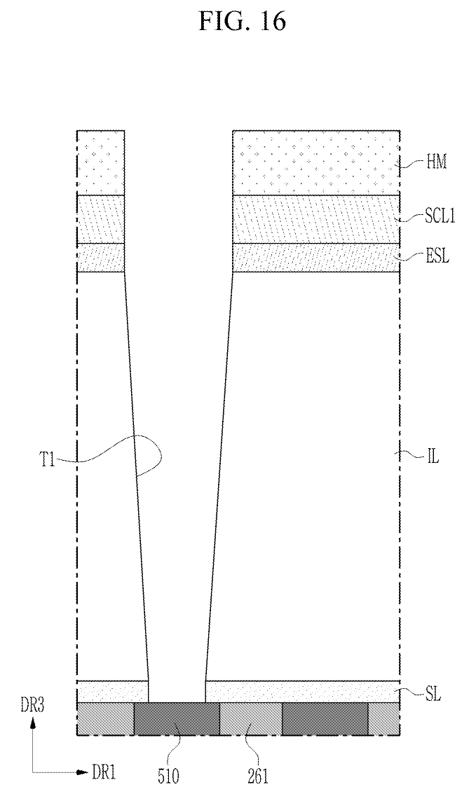

As illustrated in FIG. 16, the photoresist pattern PR may be removed, and the patterned hard mask layer HM may be used as an etching mask to etch the insulating layer IL and the lower etch stop layer SL to form the contact trench T1. The etching process may proceed until the upper surface of the circuit wiring 510 is exposed. A bottom surface of the contact trench T1 may be formed of the upper surface of the circuit wiring 510. A sidewall of the contact trench T1 may be formed of the insulating layer IL and the lower etch stop layer SL. A width of the contact trench T1 may gradually decrease as it approaches the upper surface of the circuit wiring 510.

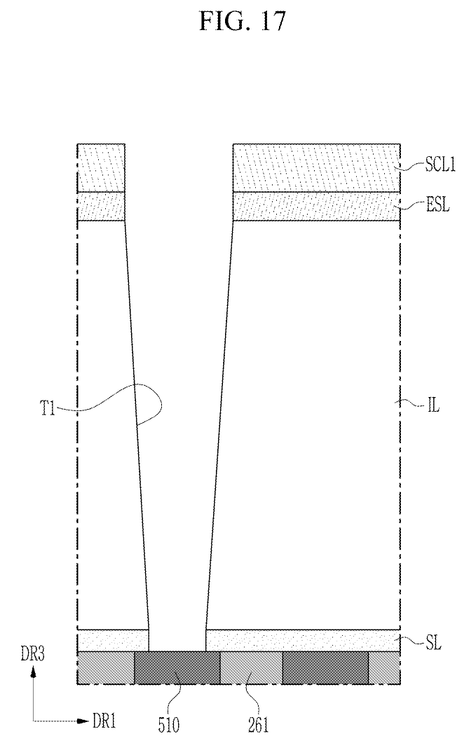

As illustrated in FIG. 17, the hard mask layer HM may be removed.

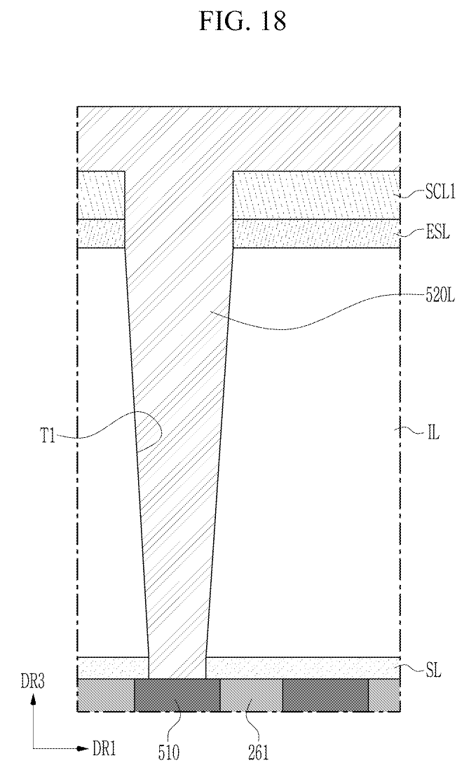

As illustrated in FIG. 18, a contact plug material layer 520L may be formed within the contact trench T1 and on the etch stop layer ESL and the first sacrificial layer SCL1 using a deposition process. The contact plug material layer 520L may fill the interior of the contact trench T1. The contact plug material layer 520L may cover an upper surface of the circuit wiring 510, an inner surface of the lower etch stop film SL, and an inner surface of the insulating layer IL within the contact trench T1. The contact plug material layer 520L may cover an inner surface of the etch stop layer ESL and an inner surface of the first sacrificial layer SCL1. The contact plug material layer 520L may cover an upper surface of the first sacrificial layer SCL1.

The contact plug material layer 520L may include a conductive material. For example, the contact plug material layer 520L may include a metal material such as tungsten (W), but is not limited thereto.

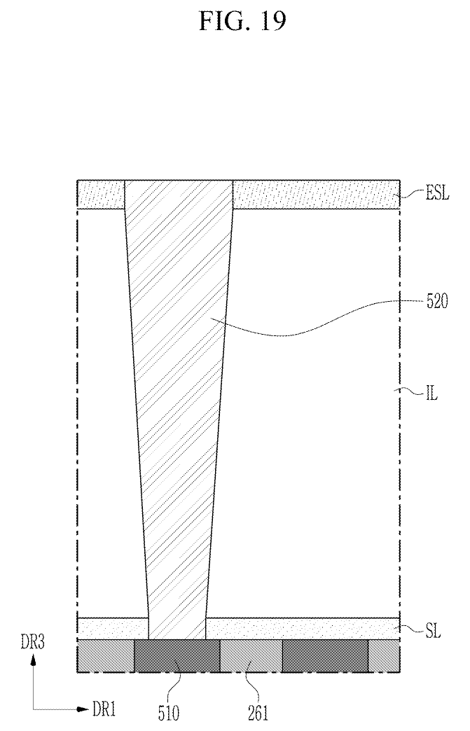

As illustrated in FIG. 19, a planarization process may be performed to form the contact plug 520. A portion of the contact plug material layer 520L may be removed by the planarization process, and the first sacrificial layer SCL1 may be completely removed. The planarization process may proceed until an upper surface of the etch stop layer ESL is exposed. However, the examples are not limited to this. For example, if the first sacrificial layer SCL1 is not formed on the etch stop layer ESL, a portion of an upper portion of the etch stop layer ESL may be removed together with the contact plug material layer 520L during the planarization process. The planarization process may be continued for a predetermined period of time after the upper surface of the etch stop layer ESL is exposed. In this case, the thickness of the etch stop layer ESL in the third direction DR3 may be reduced after the planarization process.

An upper surface of the contact plug 520 may be located at the same level as the upper surface of the etch stop layer ESL. The etch stop layer ESL may not be located on the upper surface of the contact plug 520. The etch stop layer ESL may cover a side surface of an upper portion of the contact plug 520. The etch stop layer ESL may surround an outer surface of an upper portion of the contact plug 520. The etch stop layer ESL may overlap the contact plug 520 in a direction parallel to the upper surface of the substrate 100 (e.g., in the first direction DR1), and may not overlap in a direction perpendicular to the upper surface of the substrate 100 (e.g., in the third direction DR3).

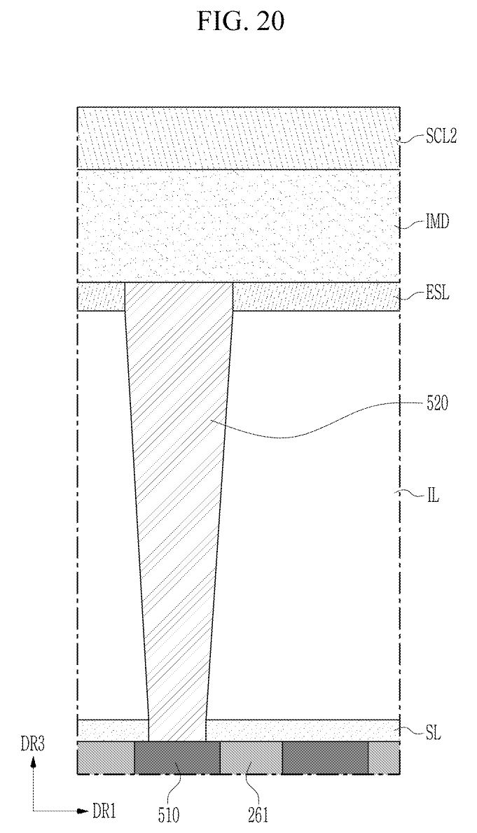

As illustrated in FIG. 20, the wiring insulating layer IMD and a second sacrificial layer SCL2 may be sequentially formed on the contact plug 520 and the etch stop layer ESL. The wiring insulating layer IMD may cover the upper surface of the contact plug 520 and the upper surface of the etch stop layer ESL.

The wiring insulating layer IMD and the second sacrificial layer SCL2 may include an insulating material. The wiring insulating layer IMD may include a material having a lower dielectric constant than the insulating layer IL.

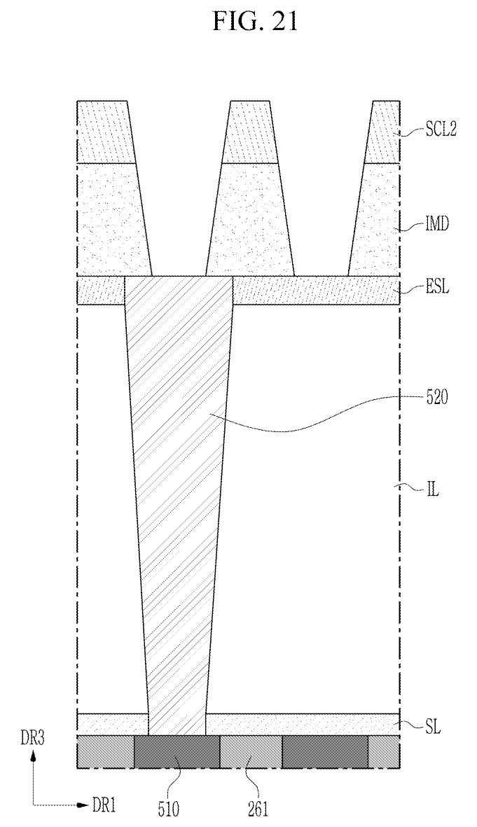

As illustrated in FIG. 21, wiring trenches T2 may be formed by patterning the wiring insulating layer IMD and the second sacrificial layer SCL2.

For example, a photoresist layer may be formed on the second sacrificial layer SCL2, and a photolithography process may be performed on the photoresist layer to form a photoresist pattern defining a region where the signal wirings 530 are to be formed. Next, an etching process may be performed using the photoresist pattern as an etching mask to pattern the wiring insulating layer IMD and the second sacrificial layer SCL2 to form the wiring trenches T2. The etching process may proceed until the upper surface of the etch stop layer ESL is exposed.

The wiring trench T2 may have a width in the first direction DR1 and a shape extending in the second direction DR2 intersecting the first direction DR1. The second direction DR2, like the first direction DR1, may be parallel to the upper surface of the substrate 100 and may be perpendicular to the first direction DR1. A bottom surface of the wiring trench T2 may be formed of the upper surface of the contact plug 520 and the upper surface of the etch stop layer ESL. A sidewall of the wiring trench T2 may be formed of the wiring insulating layer IMD and the second sacrificial layer SCL2. A width of the wiring trench T2 along the first direction DR1 may gradually decrease as it approaches the upper surface of the contact plug 520 and the upper surface of the etch stop layer ESL.

Afterwards, the photoresist pattern may be removed.

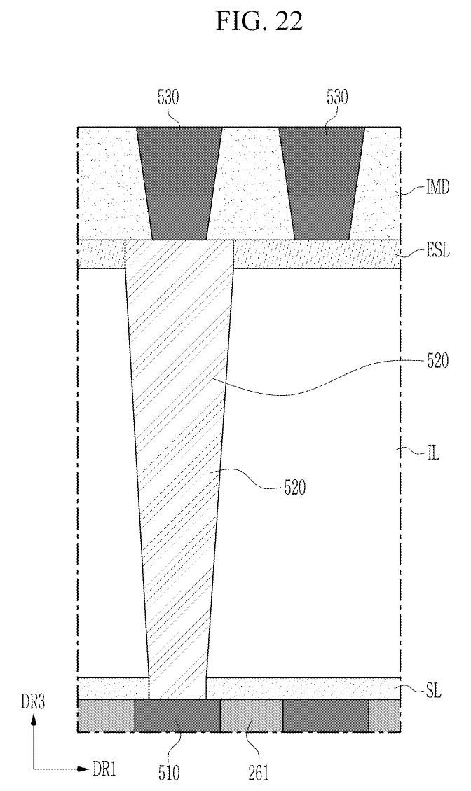

As illustrated in FIG. 22, the signal wirings 530 may be formed within the wiring trenches T2 using a deposition process and a planarization process.

First, a signal wiring material layer may be formed within the wiring trenches T2 and on an upper surface of the second sacrificial layer SCL2 using a deposition process. The signal wiring material layer may fill the interior of the wiring trench T2. The signal wiring material layer may cover an upper surface of the contact plug 520 and an upper surface of the etch stop layer ESL within the wiring trench T2, an inner surface of the wiring insulating layer IMD, and an inner surface of the second sacrificial layer SCL2. The signal wiring material layer may cover the upper surface of the second sacrificial layer SCL2.

Next, a planarization process may be performed to pattern the signal wiring material layer to form the signal wirings 530. A portion of the signal wiring material layer may be removed by the planarization process, and the second sacrificial layer SCL2 may be completely removed. The planarization process may proceed until an upper surface of the wiring insulating layer IMD is exposed. Accordingly, the signal wirings 530 may be formed separately within the wiring trenches T2.

The sides of the signal wiring 530 may be covered by the wiring insulating layer IMD. The wiring insulating layer IMD may be positioned between signal wirings 530 spaced apart and arranged in the first direction DR1.

The etch stop layer ESL may be positioned between the signal wiring 530 and the insulating layer IL. The signal wiring 530 may not penetrate the etch stop layer ESL. a lower surface of the signal wiring 530 may be located at a higher level than a lower surface of the etch stop layer ESL. The lower surface of the signal wiring 530 may be located at the same level as the upper surface of the etch stop layer ESL. The lower surface of the signal wiring 530 may be in contact with the upper surface of the contact plug 520 and the upper surface of the etch stop layer ESL.

Meanwhile, in the etching process for forming the wiring trench T2 illustrated in FIG. 21, a portion of an upper portion of the etch stop layer ESL may be etched. In an etching process, a material having a low etching selectivity of the wiring insulating layer IMD to the etch stop layer ESL and a high etching selectivity of the wiring insulating layer IMD to the contact plug 520 may be used. In this case, the speed at which the etch stop layer ESL is etched together with the wiring insulating layer IMD may be faster than the speed at which the contact plug 520 is etched. The contact plug 520 may be substantially etched. Accordingly, the upper surface of the etch stop layer ESL forming the bottom surface of the wiring trench T2 may be located at a lower level than the uppermost surface of the etch stop layer ESL. The upper surface of the contact plug 520 may be located at the same level as the uppermost surface of the etch stop layer ESL. Thereafter, as the signal wiring 530 is formed in the process of FIG. 22, a portion of a side surface of the signal wiring 530 adjacent to the lower surface of the signal wiring 530 in contact with the etch stop layer ESL may further contact the etch stop layer ESL as shown in FIGS. 6 and 7. The lower surface of the signal wiring 530 in contact with the etch stop layer ESL may be located at a lower level than the uppermost surface of the etch stop layer ESL. The lower surface of the signal wiring 530 in contact with the etch stop layer ESL may be located at a lower level than the upper surface of the contact plug 520.

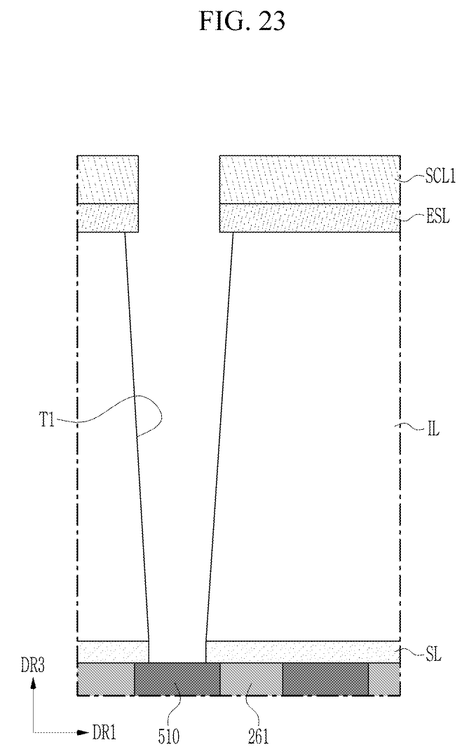

Hereinafter, a method for manufacturing a semiconductor device according to the embodiment shown in FIGS. 8 and 9 will be described with reference to FIGS. 23 to 28.

FIGS. 23 to 28 are cross-sectional views showing part of a manufacturing process of a semiconductor device according to an embodiment. FIGS. 23 to 28 are cross-sectional views showing the circuit wiring 510, the signal wiring 530, the contact plug 520 connecting the circuit wiring 510 and the signal wiring 530, and the etch stop layer ESL. The processes illustrated in FIGS. 23 to 28 may be performed subsequently after the processes of FIGS. 13 to 17 are performed.

As illustrated in FIG. 23, after forming the contact trench T1, a cleaning process may be further performed to widen a diameter of the contact trench T1. The cleaning process may be performed to improve the contact characteristics of the circuit wiring 510.

The etch stop layer ESL may include a material having etching selectivity with respect to the insulating layer IL and the lower etch stop layer SL. In the cleaning process, a material having a high etching selectivity of the insulating layer IL and the lower etch stop layer SL with respect to the etch stop layer ESL may be used. Therefore, the rate at which the etch stop layer ESL is etched in the cleaning process may be slower than the rate at which the insulating layer IL and the lower etch stop layer SL are etched. The etch stop layer ESL may remail almost unetched. Accordingly, the diameter of the contact trench T1 may be larger than a diameter of the opening of the etch stop layer ESL corresponding to the contact trench T1. A step may be formed at the boundary between the etch stop layer ESL and the insulating layer IL. A portion of a lower surface of the etch stop layer ESL may be exposed.

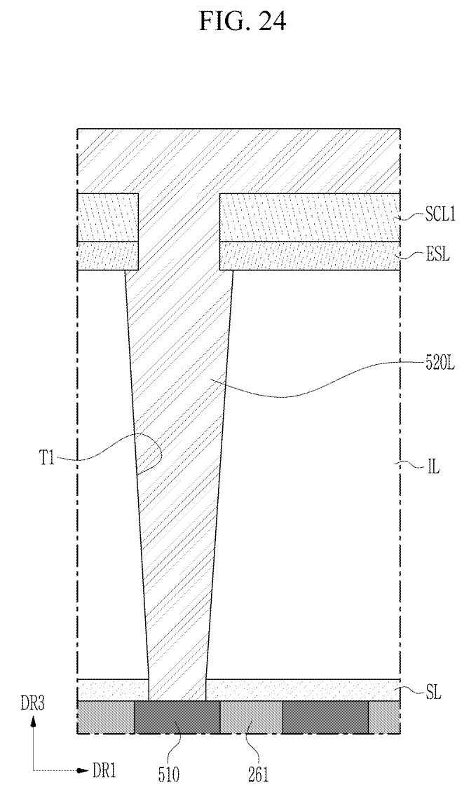

As illustrated in FIG. 24, a contact plug material layer 520L may be formed within the contact trench T1 and on the etch stop layer ESL and the first sacrificial layer SCL1 using a deposition process. The contact plug material layer 520L may fill the interior of the contact trench T1. The contact plug material layer 520L may cover an upper surface of the circuit wiring 510, an inner surface of the lower etch stop film SL, and an inner surface of the insulating layer IL within the contact trench T1. The contact plug material layer 520L may further cover a portion of the lower surface of the etch stop layer ESL within the contact trench T1. The contact plug material layer 520L may cover an inner surface of the etch stop layer ESL and an inner surface of the first sacrificial layer SCL1. The contact plug material layer 520L may cover an upper surface of the first sacrificial layer SCL1.

The contact plug material layer 520L may include a conductive material. For example, the contact plug material layer 520L may include a metal material such as tungsten (W), but is not limited thereto.

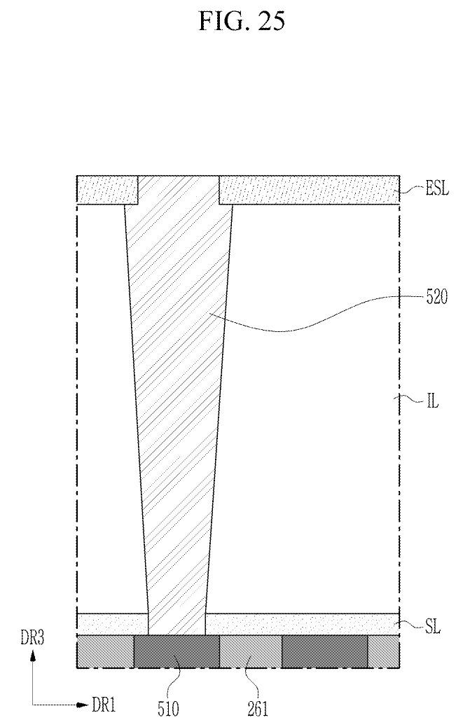

As illustrated in FIG. 25, a planarization process may be performed to form the contact plug 520. A portion of the contact plug material layer 520L may be removed by the planarization process, and the first sacrificial layer SCL1 may be completely removed. The planarization process may proceed until an upper surface of the etch stop layer ESL is exposed. However, the examples are not limited to this. For example, if the first sacrificial layer SCL1 is not formed on the etch stop layer ESL, a portion of an upper portion of the etch stop layer ESL may be removed together with the contact plug material layer 520L during the planarization process. The planarization process may be continued for a predetermined period of time after the upper surface of the etch stop layer ESL is exposed. In this case, the thickness of the etch stop layer ESL in the third direction DR3 may be reduced after the planarization process.

An upper surface of the contact plug 520 may be located at the same level as the upper surface of the etch stop layer ESL. The upper surface of the contact plug 520 may be located at the same level as the uppermost surface of the etch stop layer ESL. The etch stop layer ESL may not be located on the uppermost surface of the contact plug 520. The etch stop layer ESL may cover a side surface of an upper portion of the contact plug 520. The etch stop layer ESL may surround an outer surface of an upper portion of the contact plug 520. The contact plug 520 may cover a portion of a lower surface of the etch stop layer ESL. The etch stop layer ESL overlaps the contact plug 520 in a direction parallel to the upper surface of the substrate 100 (e.g., in the first direction DR1), and may also partially overlap in a direction perpendicular to the upper surface of the substrate 100 (e.g., in the third direction DR3).

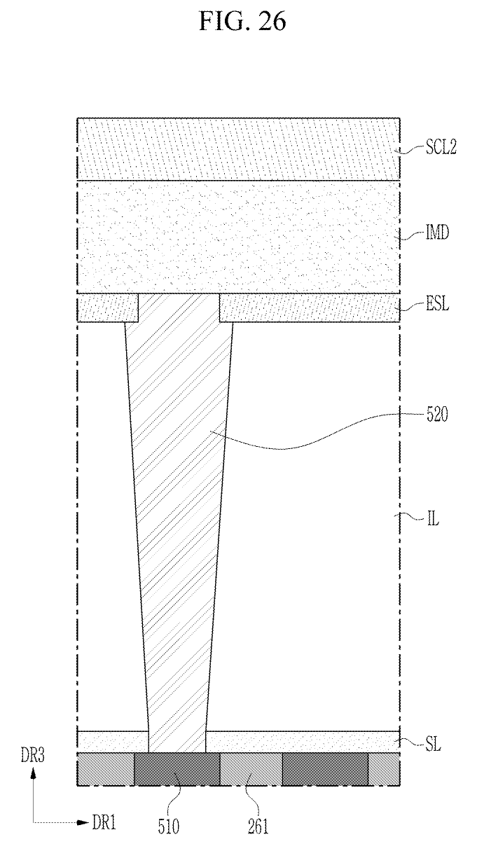

As illustrated in FIG. 26, the wiring insulating layer IMD and a second sacrificial layer SCL2 may be sequentially formed on the contact plug 520 and the etch stop layer ESL. The wiring insulating layer IMD may cover the upper surface of the contact plug 520 and the upper surface of the etch stop layer ESL.

The wiring insulating layer IMD and the second sacrificial layer SCL2 may include an insulating material. The wiring insulating layer IMD may include a material having a lower dielectric constant than the insulating layer IL.

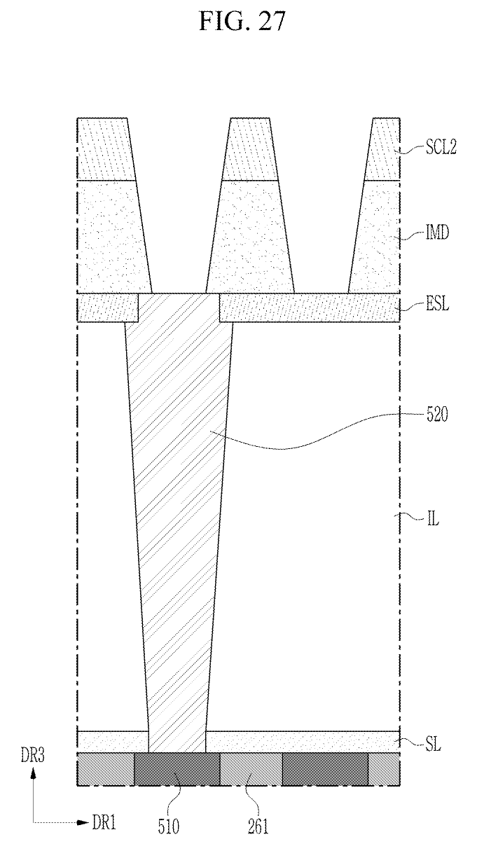

As illustrated in FIG. 27, wiring trenches T2 may be formed by patterning the wiring insulating layer IMD and the second sacrificial layer SCL2.

For example, a photoresist layer may be formed on the second sacrificial layer SCL2, and a photolithography process may be performed on the photoresist layer to form a photoresist pattern defining a region where the signal wirings 530 are to be formed. Next, an etching process may be performed using the photoresist pattern as an etching mask to pattern the wiring insulating layer IMD and the second sacrificial layer SCL2 to form the wiring trenches T2. The etching process may proceed until the upper surface of the etch stop layer ESL is exposed.

The wiring trench T2 may have a width in the first direction DR1 and a shape extending in the second direction DR2 intersecting the first direction DR1. The second direction DR2, like the first direction DR1, may be parallel to the upper surface of the substrate 100 and may be perpendicular to the first direction DR1. A bottom surface of the wiring trench T2 may be formed of the upper surface of the contact plug 520 and the upper surface of the etch stop layer ESL. A sidewall of the wiring trench T2 may be formed of the wiring insulating layer IMD and the second sacrificial layer SCL2. A width of the wiring trench T2 along the first direction DR1 may gradually decrease as it approaches the upper surface of the contact plug 520 and the upper surface of the etch stop layer ESL.

Afterwards, the photoresist pattern may be removed.

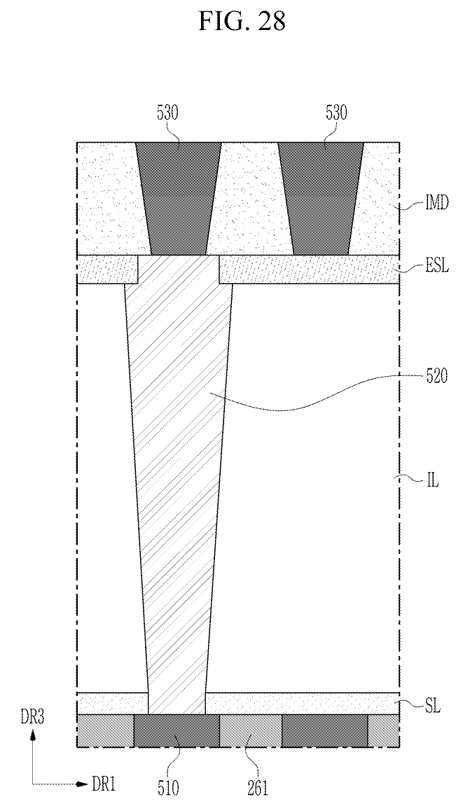

As illustrated in FIG. 28, the signal wirings 530 may be formed within the wiring trenches T2 using a deposition process and a planarization process.

First, a signal wiring material layer may be formed within the wiring trenches T2 and on an upper surface of the second sacrificial layer SCL2 using a deposition process. The signal wiring material layer may fill the interior of the wiring trench T2. The signal wiring material layer may cover an upper surface of the contact plug 520 and an upper surface of the etch stop layer ESL within the wiring trench T2, an inner surface of the wiring insulating layer IMD, and an inner surface of the second sacrificial layer SCL2. The signal wiring material layer may cover the upper surface of the second sacrificial layer SCL2.

Next, a planarization process may be performed to pattern the signal wiring material layer to form the signal wirings 530. A portion of the signal wiring material layer may be removed by the planarization process, and the second sacrificial layer SCL2 may be completely removed. The planarization process may proceed until an upper surface of the wiring insulating layer IMD is exposed. Accordingly, the signal wirings 530 may be formed separately within the wiring trenches T2.

The sides of the signal wiring 530 may be covered by the wiring insulating layer IMD. The wiring insulating layer IMD may be positioned between signal wirings 530 spaced apart and arranged in the first direction DR1.

The etch stop layer ESL may be positioned between the signal wiring 530 and the insulating layer IL. The signal wiring 530 may not penetrate the etch stop layer ESL. a lower surface of the signal wiring 530 may be located at a higher level than the lower surface of the etch stop layer ESL. The lower surface of the signal wiring 530 may be located at the same level as the upper surface of the etch stop layer ESL. The lower surface of the signal wiring 530 may be in contact with the upper surface of the contact plug 520 and the upper surface of the etch stop layer ESL.

The contact plug 520 may include the first portion 521 surrounded by the etch stop layer ESL and the second portion 522 surrounded by the insulating layer IL. The second portion 522 may extend from the first portion 521 in a direction perpendicular to the upper surface of the substrate 100 (e.g., in the third direction (DR3)). A diameter of the second portion 522 of the contact plug 520 may gradually decrease as it gets farther away from the signal wiring 530. The diameter of the second portion 522 of the contact plug 520 may be larger as it approaches the first portion 521 of the contact plug 520. A diameter of the first portion 521 of the contact plug 520 may be smaller than the diameter of the second portion 522 of the contact plug 520 adjacent to the first portion 521. The diameter D1 of the first portion 521 of the contact plug 520 may be smaller than the maximum diameter D2 of the second portion 522 of the contact plug 520. Among the second portion 522 of the contact plug 520, the part closest to the first portion 521 of the contact plug 520 may have the maximum diameter.

Meanwhile, in the etching process for forming the wiring trench T2 illustrated in FIG. 27, a portion of an upper portion of the etch stop layer ESL may be etched. In this case, depending on the etching selectivity of the contact plug 520 and the etching stop layer ESL, the speed at which the etching stop layer ESL is etched may be faster than the speed at which the contact plug 520 is etched. The contact plug 520 may be substantially etched. Accordingly, the upper surface of the etch stop layer ESL forming the bottom surface of the wiring trench T2 may be located at a lower level than the uppermost surface of the etch stop layer ESL. An upper surface of the first portion 521 of the contact plug 520 may be positioned at the same level as the uppermost surface of the etch stop layer ESL. Thereafter, as the signal wiring 530 is formed in the process of FIG. 28, a portion of a side surface of the signal wiring 530 adjacent to the lower surface of the signal wiring 530 in contact with the etch stop layer ESL may further contact the etch stop layer ESL as shown in FIGS. 10 and 11. The lower surface of the signal wiring 530 in contact with the etch stop layer ESL may be located at a lower level than the uppermost surface of the etch stop layer ESL. The lower surface of the signal wiring 530 in contact with the etch stop layer ESL may be located at a lower level than the upper surface of the first portion 521 of the contact plug 520.

Although the embodiments of the present invention have been described in detail above, the scope of the present invention is not limited thereto, and various modifications and improvements made by those skilled in the art using the basic concept of the present invention defined in the following claims also fall within the scope of the present invention.

What is claimed is:

1. A semiconductor device comprising:
a substrate including a cell array region and a core/periphery region disposed around the cell array region,
a circuit wiring disposed on the core/periphery region of the substrate;
a signal wiring disposed apart from the circuit wiring in a direction perpendicular to an upper surface of the substrate,
a contact plug connecting the circuit wiring and the signal wiring,
an etch stop layer surrounding an outer surface of an upper portion of the contact plug, and
a wiring insulating layer covering an upper surface of the contact plug and an upper surface of the etch stop layer, and covering a side surface of the signal wiring,
wherein a lower surface of the signal wiring is positioned at a higher level than a lower surface of the etch stop layer.

2. The semiconductor device of claim 1,
wherein the upper surface of the etch stop layer is positioned at the same level as the upper surface of the contact plug.

3. The semiconductor device of claim 1,
wherein the signal wiring is positioned on the contact plug and the etch stop layer, and
wherein the signal wiring includes a first portion in contact with the contact plug and a second portion in contact with the etch stop layer.

4. The semiconductor device of claim 3,
wherein a lower surface of the second portion of the signal wiring is in contact with the upper surface of the etch stop layer.

5. The semiconductor device of claim 3,
wherein a portion of a side surface of the second portion adjacent to a lower surface of the second portion of the signal wiring is in further contact with the etch stop layer.

6. The semiconductor device of claim 1,
wherein the contact plug includes a first portion surrounded by the etch stop layer and a second portion extending from the first portion toward the upper surface of the substrate, and
wherein a diameter of the first portion of the contact plug is smaller than a diameter of the second portion of the contact plug adjacent to the first portion of the contact plug.

7. The semiconductor device of claim 6,
wherein an upper surface of the first portion of the contact plug is positioned at the same level as the upper surface of the etch stop layer.

8. The semiconductor device of claim 6,
wherein the first portion of the contact plug overlaps the etch stop layer in a first direction parallel to the upper surface of the substrate, and
wherein the second portion of the contact plug overlaps the etch stop layer in a second direction perpendicular to the upper surface of the substrate.

9. The semiconductor device of claim 6,
wherein an upper surface of the second portion of the contact plug is in contact with the lower surface of the etch stop layer.

10. The semiconductor device of claim 6,
wherein the signal wiring is positioned on the contact plug and the etch stop layer, and
wherein the signal wiring includes a third portion in contact with the contact plug and a fourth portion in contact with the etch stop layer.

11. The semiconductor device of claim 10,
wherein a lower surface of the fourth portion of the signal wiring is positioned at the same level as the upper surface of the etch stop layer.

12. The semiconductor device of claim 10,
wherein a lower surface of the fourth portion of the signal wiring is positioned at a lower level than the upper surface of the contact plug.

13. The semiconductor device of claim 1,
further comprising an insulating layer surrounding an outer surface of a lower portion of the contact plug,
wherein the insulating layer includes a material having a higher dielectric constant than the wiring insulating layer, and
wherein the etch stop layer is positioned between the signal wiring and the insulating layer.

14. The semiconductor device of claim 1,
wherein a lower end of the contact plug is in contact with an upper surface of the circuit wiring.

15. The semiconductor device of claim 1, further comprising:
a capacitor positioned on the cell array region of the substrate, the capacitor including a lower electrode, an upper electrode, and a dielectric layer positioned between the lower electrode and the upper electrode,
wherein a lower end of the contact plug is in contact with an upper surface of the upper electrode of the capacitor, and
wherein the upper electrode of the capacitor is electrically connected to the circuit wiring.

16. A semiconductor device comprising:
a substrate including a cell array region and a core/periphery region disposed around the cell array region,
a circuit wiring disposed on the core/periphery region of the substrate;
an insulating layer disposed on the cell array region and the core/periphery region of the substrate and covering the circuit wiring;
a signal wiring and a wiring insulating layer disposed on the insulating layer, the wiring insulating layer covering a side surface of the signal wiring,
an etch stop layer disposed between the insulating layer and the wiring insulating layer, and
a contact plug connecting the signal wiring and the circuit wiring,
wherein an upper surface of the contact plug is in contact with the signal wiring and the wiring insulating layer, and
wherein a side surface of the contact plug is in contact with the etch stop layer and the insulating layer.

17. The semiconductor device of claim 16,
wherein the etch stop layer is further positioned between the insulating layer and the signal wiring.

18. The semiconductor device of claim 17,
wherein the signal wiring includes a first portion in contact with the upper surface of the contact plug and a second portion in contact with an upper surface of the etch stop layer.

19. The semiconductor device of claim 16,
wherein the contact plug includes a first portion in contact with the etch stop layer and a second portion in contact with the insulating layer,
wherein a diameter of the second portion gradually decreases as it moves away from the first portion,
wherein a diameter of the first portion is smaller than a maximum diameter of the second portion.

20. A semiconductor device comprising:
a substrate including a cell array region and a core/periphery region disposed around the cell array region,
a circuit wiring disposed on the core/periphery region of the substrate;
an insulating layer disposed on the cell array region and core/periphery region of the substrate and covering the circuit wiring;
a signal wiring and a wiring insulating layer disposed on the insulating layer, the wiring insulating layer covering a side surface of the signal wiring,
an etch stop layer disposed between the insulating layer and the wiring insulating layer, and
a contact plug connecting the signal wiring and the circuit wiring,
wherein the etch stop layer is in contact with a side surface of the contact plug and in contact with a lower surface of the signal wiring.
